(19) United States
(12) Patent Application Publication
(10) Pub. No.: US 2025/0279750 A1
(43) Pub. Date: Sep. 4, 2025

(54) TRACKER MODULE AND COMMUNICATION DEVICE

(71) Applicant: Murata Manufacturing Co., Ltd., Nagaokakyo-shi (JP)

(72) Inventors: Naohide Tomita, Nagaokakyo-shi (JP); Kenzou Oomori, Nagaokakyo-shi (JP); Toshiki Matsui, Nagaokakyo-shi (JP)

(21) Appl. No.: 19/212,938

(22) Filed: May 20, 2025

Related U.S. Application Data
(63) Continuation of application No. PCT/JP2023/044462, filed on Dec. 12, 2023.

(30) Foreign Application Priority Data
Dec. 22, 2022 (JP) 2022-205931

(51) Int. Cl. H03F 1/02; H03F 3/24; H04B 1/04

(52) U.S. Cl. CPC H03F 1/02; H03F 3/24; H04B 1/04; H03F 2200/102; H03F 2200/36; H03F 2200/451; H04B 2001/0433

(57) ABSTRACT

An ET module is provided that includes a module laminate; a first external output terminal and a second external input terminal disposed on the module laminate; and a voltage supply circuit disposed on the module laminate and configured to supply a voltage based on an envelope signal to a PA module through the first external output terminal. The second external input terminal is connected to a first path that connects the first external output terminal to the PA module. The second external input terminal and the first external output terminal are disposed adjacent to each other.

### CROSS REFERENCE TO RELATED APPLICTIONS

This application is a continuation of International Application No. PCT/JP2023/044462, filed Dec. 12, 2023, which claims priority to Japanese Patent Application No. 2022-205931, filed Dec. 22, 2022, the contents of each of which are hereby incorporated by reference in their entirety.

### TECHNICAL FIELD

The present disclosure relates to a tracker module and a communication device.

### BACKGROUND

In recent years, a power added efficiency (hereinafter referred to as an “efficiency”) has been improved by application of envelope tracking (ET: Envelope Tracking) to a power amplifier circuit. In ET systems, for example, a digital ET technology for supplying a plurality of discrete voltages has been disclosed.

For example, U.S. Pat. No. 9,755,672 discloses a supply modulator (e.g., a tracker circuit) that supplies a power supply voltage to a power amplifier circuit based on an envelope signal. The above-mentioned supply modulator includes a magnetic converter circuit (Magnetic Regulation Stage: Pre-regulator circuit) that converts a voltage; a switched-capacitor circuit (Switched-Capacitor Voltage Balance Stage) that generates, from the voltage, a plurality of voltages having different voltage levels; and an output switching circuit (Output Switching Stage) that selects and outputs at least one of the plurality of voltages. The magnetic converter circuit includes a switch and a power inductor, the switched-capacitor circuit includes a switch and a capacitor, and the output switching circuit includes a switch.

However, if a tracker circuit is modularized in an ET system, efficiency of the tracker circuit may deteriorate depending on an arrangement configuration of a voltage output path that outputs a voltage from the tracker circuit to a power amplifier circuit and a voltage input path that inputs the above voltage from the voltage output path to the tracker circuit.

### SUMMARY OF THE INVENTION

In view of the foregoing, a tracker module and a communication device are provided that suppresses efficiency deterioration.

In an exemplary aspect, a tracker module is provided that includes a module laminate; a first external output terminal and a first external input terminal disposed on the module laminate; and a voltage supply circuit disposed on the module laminate and configured to supply a voltage based on an envelope signal to a power amplifier through the first external output terminal. The first external input terminal is connected to a first path that connects the first external output terminal to the power amplifier. Moreover, the first external input terminal and the first external output terminal are disposed adjacent to each other.

In another exemplary aspect, a tracker module is provided that includes a module laminate; a first external output terminal and a first external input terminal disposed on the module laminate; and a voltage supply circuit including at least one integrated circuit disposed on the module laminate. The voltage supply circuit includes at least one switch included in a switched-capacitor circuit and at least one switch included in a first output switching circuit. The switched-capacitor circuit is configured to generate a plurality of discrete voltages based on an input voltage and output the generated plurality of discrete voltages to the first output switching circuit. The first output switching circuit is configured to selectively output at least one of the generated plurality of discrete voltages to a power amplifier via the first external output terminal. The first external input terminal is connected to a first path that connects the first external output terminal to the power amplifier. The first external input terminal and the first external output terminal are disposed adjacent to each other.

According to the exemplary aspect of the present disclosure, a tracker module and a communication device are provided that suppresses efficiency deterioration.

### BRIEF DESCRIPTION OF DRAWINGS

FIG. 1A is a graph illustrating an example of a transition in a power supply voltage in an average power tracking (APT: Average Power Tracking) mode.

FIG. 1B is a graph illustrating an example of a transition in a power supply voltage in an analog ET mode.

FIG. 1C is a graph illustrating an example of a transition in a power supply voltage in a digital ET mode.

FIG. 2 is a circuit configuration diagram of a tracker module and a communication device according to an exemplary embodiment.

FIG. 3 is a circuit configuration diagram of a tracker module and a communication device according to Example 1.

FIG. 4 is a diagram of circuit configurations of a pre-regulator circuit, a switched-capacitor circuit, output switching circuits, and filter circuits according to Example 1.

FIG. 5 is a circuit configuration diagram of a tracker module and a communication device according to Example 2.

FIG. 6A is a plan view of the tracker module according to Example 1.

FIG. 6B is a plan view of the tracker module according to Example 1.

FIG. 6C is a cross-sectional view of the tracker module according to Example 1.

FIG. 7 is a plan view of the communication device according to Example 1.

FIG. 8A is a plan view of a communication device according to Example 2.

FIG. 8B is a plan view of a communication device according to Modification Example 1.

FIG. 9 is a circuit configuration diagram of a tracker module and a communication device according to another exemplary embodiment.

FIG. 10 is a plan view of the communication device according to Example 3.

FIG. 11 is a plan view of a communication device according to Modification Example 2.

### DETAILED DESCRIPTION OF EMBODIMENTS

In the following, embodiments of the present disclosure are described in detail with reference to the drawings. All embodiments to be described below illustrate comprehensive and specific examples. Numeric values, shapes, materials, components, and an arrangement and a connection form of the components, which are described in the following embodiments, are merely examples and are not intended to limit the exemplary aspects of the present disclosure.

It is noted that each figure is a schematic diagram that is appropriately emphasized, omitted, or subjected to ratio adjustment in order to illustrate the exemplary aspects of the present disclosure. Each figure is not necessarily a strict illustration and may differ from an actual shape, a positional relationship, or a ratio. In each figure, an identical numeral is given to a substantially identical configuration, and an overlapping description may be omitted or simplified.

In each figure below, an x-axis and a y-axis are axes orthogonal to each other on a plane parallel to a main surface of a board. Specifically, in an exemplary aspect where a board has a rectangular shape in plan view, the x-axis is parallel to a first side of the board, and the y-axis is parallel to a second side that is orthogonal to the first side of the board. In addition, a z-axis is an axis perpendicular to the main surface of the board, a positive direction of which indicates an upward direction and a negative direction of which indicates a downward direction.

In a circuit configuration of the present disclosure, the phrase “to be connected” includes a case where a connection terminal and/or a wiring conductor is directly connected, and a case in which a connection terminal and/or a wiring conductor is electrically connected via another circuit element. Moreover, the phrase “to be connected between A and B” can refer to a connection with both A and B between A and B.

In a component arrangement of the exemplary aspects of the present disclosure, the phrase “a component disposed in or on a board” includes a component being disposed on a main surface of a board and a component being disposed in a board. Moreover, the phrase “a component being disposed on a main surface of a board” includes not only a component being disposed in contact with a main surface of a board, but also a component being disposed above the main surface without being in contact therewith (for example, a component being laminated on another component that is disposed in contact with a main surface). In addition, the phrase “a component being disposed on a main surface of a board” may include a component being disposed in a recessed portion formed on a main surface. Moreover, the phrase “a component being disposed in a board” includes not only a component being encapsuled within a board but also an entire component being disposed between both main surfaces of a board, but a portion of the component not being covered with the board, and only a portion of the component being disposed in the board.

In the component arrangement of the exemplary aspects of the present disclosure, the phrase “in plan view of a board” can refer to viewing, from a z-axis positive side, an object or component orthographically projected on an xy-plane. The phrase “A overlapping with B in plan view” can mean that at least a portion of a region of A orthographically projected on the xy-plane overlaps with at least a portion of a region of B orthographically projected on the xy-plane. In addition, the phrase “A being disposed between B and C” can mean that at least one of a plurality of line segments connecting an arbitrary point in B and an arbitrary point in C passes through A.

In addition, in the component arrangement of the exemplary aspects of the present disclosure, the phrase “A being disposed adjacent to B” represents that A and B are disposed in proximity, and specifically can mean that no other circuit component is present in a space in which A faces B. In other words, the phrase “A being disposed adjacent to B” means that none of a plurality of line segments reaching B, from an arbitrary point on a surface of A facing B, along a normal direction of the surface, passes through any circuit component other than A and B. Here, a circuit component can refer to a component including an active element and/or a passive element. More specifically, a circuit component includes an active component including a transistor or a diode, or the like, and a passive component including an inductor, a transformer, a capacitor, or a resistor, or the like, and does not include an electromechanical component including a terminal, a connector, or a wiring line, or the like.

In the exemplary aspects of the present disclosure, a “terminal” can refer to a point where a conductor within an element terminates. It is noted that when an impedance of a conductor between elements is sufficiently low, a terminal is construed not only as a single point but also as an arbitrary point on the conductor between the elements or the entire conductor.

In the component arrangement of the exemplary aspects of the present disclosure, the phrase “component A being disposed in series on path B” can refer to both a signal input terminal and a signal output terminal of the component A are connected to a wiring line, an electrode, or a terminal that form the path B.

In addition, terms that indicate a relationship between elements, such as “parallel” or “perpendicular”, and terms that indicate a shape of an element, such as “rectangular”, as well as a numerical range do not only indicate a strict meaning, but also may include a substantially equivalent range, for example, an error such as a few percent.

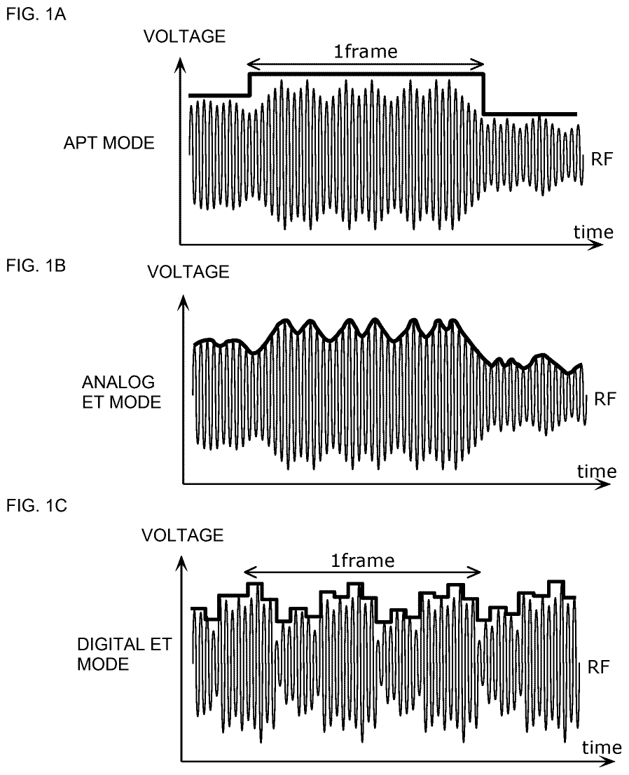

First, as a technology for amplifying radio frequency signals highly efficiently, a tracking mode is described that supplies a power amplifier with a power supply voltage to be dynamically adjusted over time based on the radio frequency signal. The tracking mode is a mode that dynamically adjusts a power supply voltage to be applied to the power amplifier. Although there are several types of tracking modes, here, an average power tracking (APT: Average Power Tracking) mode and an ET (ET: Envelope Tracking mode (including an analog ET mode and a digital ET mode) are described with reference to FIGS. 1A to 1C. In FIGS. 1A to 1C, a horizontal axis represents time, and a vertical axis represents a voltage. In addition, a thick solid line represents a power supply voltage, and a thin solid line (waveform) represents a modulated signal.

FIG. 1A is a graph illustrating an example of a transition in a power supply voltage in the APT mode. In the APT mode, a power supply voltage is fluctuated to a plurality of discrete voltage levels in units of one frame based on average power. As a result, a power supply voltage signal forms a rectangular wave.

According to an exemplary aspect, a frame can refer to a unit that forms a radio frequency signal (e.g., a modulated signal). For example, in 5GNR (5^{th} Generation New Radio) and LTE (Long Term Evolution), a frame includes 10 subframes, each subframe including a plurality of slots, each slot being composed of a plurality of symbols. A subframe has a length of 1 ms, and a frame has a length of 10 ms according to an exemplary aspect.

It is noted that for purposes of this disclosure, a mode of fluctuating a voltage level in units of one frame or larger based on the average power is referred to as the APT mode, and is distinguished from a mode that fluctuates the voltage level in units smaller than one frame (for example, a subframe, a slot, or a symbol). For example, a mode that fluctuates the voltage level in symbol units is referred to as a symbol power tracking (SPT: Symbol Power Tracking) mode and is distinguished from the APT mode.

FIG. 1B is a graph illustrating an example of a transition in a power supply voltage in an analog ET mode. In the analog ET mode, an envelope of the modulated signal is tracked by continuously fluctuating the power supply voltage based on an envelope signal.

An envelope signal is a signal representing an envelope of a modulated signal. An envelope value is expressed by, for example, a root square of (I²+Q²). Here, (I, Q) represents a constellation point. Moreover, for purposes of this disclosure, a constellation point refers to a point that represents a signal modulated by digital modulation on a constellation diagram. (I, Q) is determined by, for example, BBIC (Baseband Integrated Circuit) based on, for example, transmission information.

FIG. 1C is a graph illustrating an example of a transition in a power supply voltage in a digital ET mode. In the digital ET mode, an envelope of a modulated signal is tracked by fluctuating the power supply voltage to a plurality of discrete voltage levels in one frame based on an envelope signal. As a result, the power supply voltage signal forms a rectangular wave.

### Exemplary Embodiments

### 1. Circuit Configuration of ET Module 1 and Communication Device 5

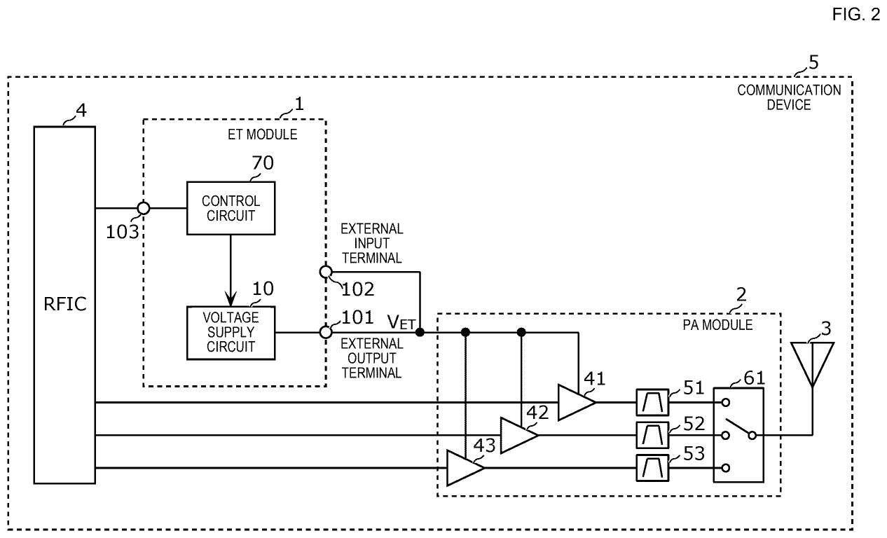

An ET module 1 and a communication device 5 according to the present embodiment are described with reference to FIG. 2.

FIG. 2 is a circuit configuration diagram of the ET module 1 and the communication device 5 according to the present embodiment. The communication device 5 according to the present embodiment corresponds to a user terminal (UE User Equipment) in a cellular network, and is typically a mobile phone, a smart phone, a tablet computer, a wearable device, or the like. It is noted that the communication device 5 can be an IoT (Internet of Things) sensor device, a medical/healthcare device, an automobile, an unmanned aerial vehicle (UAV: Unmanned Aerial Vehicle) (a so-called drone), and an automated guided vehicle (AGV: Automated Guided Vehicle).

First, a circuit configuration of the communication device 5 is described. As illustrated in FIG. 2, the communication device 5 according to the present embodiment includes the ET module 1, PA module 2, antenna 3, and an RFIC (Radio Frequency Integrated Circuit) 4.

The antenna 3 is connected to the PA module 2 and transmits a radio frequency signal output from the PA module 2.

The RFIC 4 is an example of a signal processing circuit that processes radio frequency signals. The RFIC 4 has a control section that controls the PA module 2. Specifically, the RFIC 4 performs signal processing on a transmission signal input from the BBIC (not illustrated) by up-conversion, or the like, and outputs a radio frequency transmission signal generated by the signal processing to the PA module 2. In addition, the RFIC 4 outputs a digital control signal that controls the ET module 1 to the ET module 1. It is noted that some or all of capabilities of the RFIC 4 as the control section may be implemented externally to the RFIC 4, and may be implemented, for example, in the BBIC, the PA module 2, and the ET module 1.

The ET module 1 supplies a power supply voltage V_{ET} to the PA module 2. The power supply voltage V_{ET} is an example of a voltage based on an envelope signal. The ET module 1 can supply the power supply voltage V_{ET} to the PA module 2 in at least any of the APT mode, the analog ET mode, and the digital ET mode illustrated in FIGS. 1A to 1C.

As illustrated in FIG. 2, the ET module 1 includes a voltage supply circuit 10, a control circuit 70, an external output terminal 101, an external input terminal 102, and control signal terminal 103.

The voltage supply circuit 10 is configured to supply the power supply voltage V_{ET} based on the envelope signal to the PA module 2 through the external output terminal 101. Specifically, the voltage supply circuit 10 receives a control signal output from the control circuit 70 to generate the power supply voltage V_{ET}, and outputs the power supply voltage V_{ET} to the external output terminal 101. The voltage supply circuit 10 is, for example, a DC-DC converter that steps up or down a pressure of magnetic energy generated by an inductor of the DC-DC converter and outputs the magnetic energy, as the power supply voltage V_{ET}. It is noted that the inductor that generates the magnetic energy may be located externally to the ET module 1 in an exemplary aspect.

The external output terminal 101 is an example of a first external output terminal that can be connected externally and is connected to the voltage supply circuit 10 and the PA module 2. The power supply voltage V_{ET}, which is generated by the voltage supply circuit 10, is applied to the external output terminal 101.

The external input terminal 102 is an example of a first external input terminal that can be connected externally and is connected to a first path connecting the external output terminal 101 and the PA module 2. In operation, when the analog ET mode is applied to the ET module 1, the external input terminal 102 can be configured to function as a terminal for feeding back the power supply voltage V_{ET} on the first path to the ET module 1, and is connected to the voltage supply circuit 10 or the control circuit 70 within the ET module 1. In addition, when the APT mode is applied to the ET module 1, the external input terminal 102 can be configured to function as a terminal for stabilizing the power supply voltage VET on the first path, and is connected to a capacitor, for example.

The control circuit 70 is an example of a control section of the ET module 1 and is connected to the control signal terminal 103 and the voltage supply circuit 10. The control circuit 70 controls the voltage supply circuit 10 to output the power supply voltage VET from the voltage supply circuit 10, based on an envelope signal input from the RFIC 4 via the control signal terminal 103, target power supply voltage information of the PA module 2, and a feedback power supply voltage input via the external input terminal 102.

The PA module 2 receives supply of the power supply voltage V_{ET} from the ET module 1, amplifies a radio frequency transmission signal input from the RFIC 4, and outputs the amplified radio frequency transmission signal to the antenna 3. The PA module 2 includes power amplifiers 41, 42, and 43, filters 51, 52, and 53, and a switch 61.

Each of the power amplifiers 41 to 43 is connected between the ET module 1 and the antenna 3. Specifically, a supply terminal of the power amplifier 41 is connected to the ET module 1, a radio frequency input terminal is connected to the RFIC 4, and a radio frequency output terminal is connected to the antenna 3 via the filter 51 and the switch 61. A supply terminal of the power amplifier 42 is connected to the ET module 1, a radio frequency input terminal is connected to the RFIC 4, and a radio frequency output terminal is connected to the antenna 3 via the filter 52 and the switch 61. A supply terminal of the power amplifier 43 is connected to the ET module 1, a radio frequency input terminal is connected to the RFIC 4, and a radio frequency output terminal is connected to the antenna 3 via the filter 53 and the switch 61. The power amplifier 41 can amplify a radio frequency signal of band A, the power amplifier 42 can amplify a radio frequency signal of band B, and the power amplifier 43 can amplify a radio frequency signal of band C.

The filter 51 includes the band A as a pass band, for example. The filter 52 includes the band B as a pass band, for example. The filter 53 includes the band C as a pass band, for example.

It is noted that each of the band A, the band B, and the band C is a frequency band for a communication system that is built using a radio access technology (RAT: Radio Access Technology), and is predefined by a standardizing body (for example, 3GPP® (3rd Generation Partnership Project) and IEEE (Institute of Electrical and Electronics Engineers), or the like). Examples of communication systems include a 5GNR (5^{th} Generation New Radio) system, an LTE (Long Term Evolution) system, and a WLAN (Wireless Local Area Network) system, or the like.

The switch 61 has a common terminal and three selection terminals, and switches connection between the common terminal and any one of the three selection terminals. The common terminal of the switch 61 is connected to the antenna 3, a first selection terminal is connected to the filter 51, a second selection terminal is connected to the filter 52, and a third selection terminal is connected to the filter 53.

According to a configuration of the PA module 2 described above, the PA module 2 can amplify a radio frequency signal of any one of the band A, the band B, and the band C, and output the amplified radio frequency signal to the antenna 3.

A node on the first path connecting each of the supply terminals of the power amplifiers 41 to 43 and the external output terminal 101 is connected to the external input terminal 102.

### 2. Circuit Configuration of ET Module 1A and Communication Device 5A According to Example 1

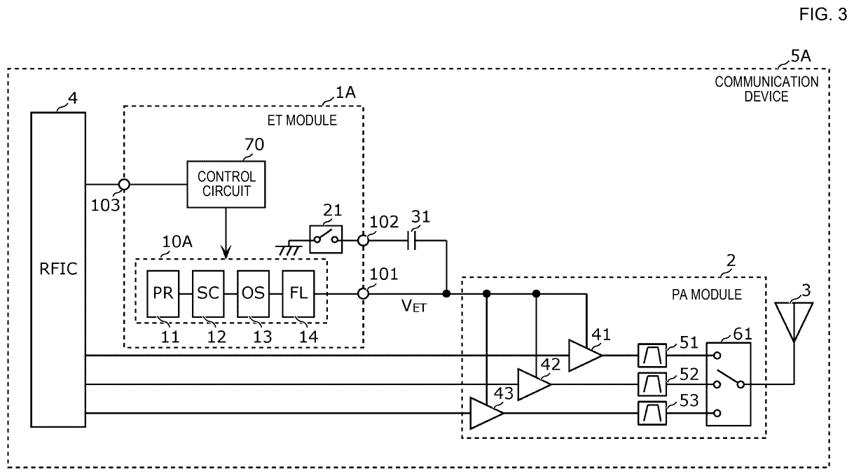

FIG. 3 is a circuit configuration diagram of an ET module 1A and the communication device 5A according to Example 1. The ET module 1A and the communication device 5A according to this Example are examples of the ET module 1 and the communication device 5 according to the present embodiment and illustrate a specific circuit configuration of the ET module 1.

The communication device 5A according to this Example includes the ET module 1A, the PA module 2, capacitor 31, antenna 3, and the RFIC 4. As compared to the communication device 5 according to the embodiment, the communication device 5A according to this Example differs in that a configuration of the ET module 1A, and the capacitor 31 are added. Therefore, in the following, the communication device 5A according to this Example is described with a focus on configurations of the ET module 1A and the capacitor 31.

The ET module 1A is an example of a tracker module, and can supply the power supply voltage V_{ET}, which is one of a plurality of discrete voltages, to the PA module 2. The digital ET mode and the APT mode can be used as a tracking mode, but the tracking mode is not limited thereto. As illustrated in FIG. 3, the ET module 1A includes a voltage supply circuit 10A, the control circuit 70, switch 21, the external output terminal 101, the external input terminal 102, and the control signal terminal 103. As compared to the ET module 1 according to the embodiment, the ET module 1A according to this Example differs in that a configuration of the voltage supply circuit 10A and the switch 21 are added. In the following, the ET module 1A according to this Example is described, omitting the same configurations as those of the ET module 1 according to the embodiment and focusing on different configurations.

The voltage supply circuit 10A includes a pre-regulator circuit 11, a switched-capacitor circuit 12, an output switching circuit 13, and a filter circuit 14.

The pre-regulator circuit 11 is an example of a converter circuit and includes a power inductor and a switch. A power inductor is an inductor used to step up and/or down a direct current (DC: Direct Current) voltage. The power inductor is connected in series to a direct current path. It is noted that the power inductor may be connected (e.g., disposed in parallel) between the direct current path and a ground in an exemplary aspect. The pre-regulator circuit 11 can use the power inductor to convert an input voltage into a first voltage. In some cases, such a pre-regulator circuit 11 may be referred to as a magnetic regulator or a DC-DC converter according to an exemplary aspect.

The switched-capacitor circuit 12 includes a plurality of capacitors and a plurality of switches and can generate a plurality of discrete voltages from input voltages from the pre-regulator circuit 11. The switched-capacitor circuit 12 may be referred to as a switched-capacitor voltage balancer (Switched-Capacitor Voltage Balancer) according to an exemplary aspect.

The output switching circuit 13 is an example of a first output switching circuit and is configured to selectively output at least one of the plurality of discrete voltages generated by the switched-capacitor circuit 12 to the PA module 2 via the external output terminal 101. The output switching circuit 13 is controlled based on a digital control signal.

The filter circuit 14 can attenuate noise from the plurality of discrete voltages supplied to the PA module 2. The filter circuit 14 may be referred to as pulse shaping filters or transition shaping filters according to an exemplary aspect.

It is noted that the voltage supply circuit 10A may not include the filter circuit 14 in an exemplary aspect. In addition, any combination of the pre-regulator circuit 11, the switched-capacitor circuit 12, the output switching circuit 13, and the filter circuit 14 may be integrated into a single circuit. Alternatively, the voltage supply circuit 10A may include a plurality of voltage supply circuits, instead of the pre-regulator circuit 11 and the switched-capacitor circuit 12. In this case, the output switching circuit 13 may be each configured to select at least one of the plurality of voltage supply circuits.

The switch 21 is an example of a first switch circuit and is connected between the external input terminal 102 and the ground to switch between connection and disconnection between the external input terminal 102 and the ground.

The capacitor 31 is disposed in series between the external input terminal 102 and a node on the first path.

In operation, when the digital ET mode is applied to the ET module 1A, for example, the switch 21 is in a non-conductive state, so that a radio frequency signal of a wide channel band width (wide modulation band width) can be amplified highly efficiently in the PA module 2. In addition, when the APT mode is applied to the ET module 1A, for example, the switch 21 are in a conductive state, so that the capacitor 31 can be configured to function as bypass condensers, and voltage levels of the power supply voltage V_{ET} can be stabilized.

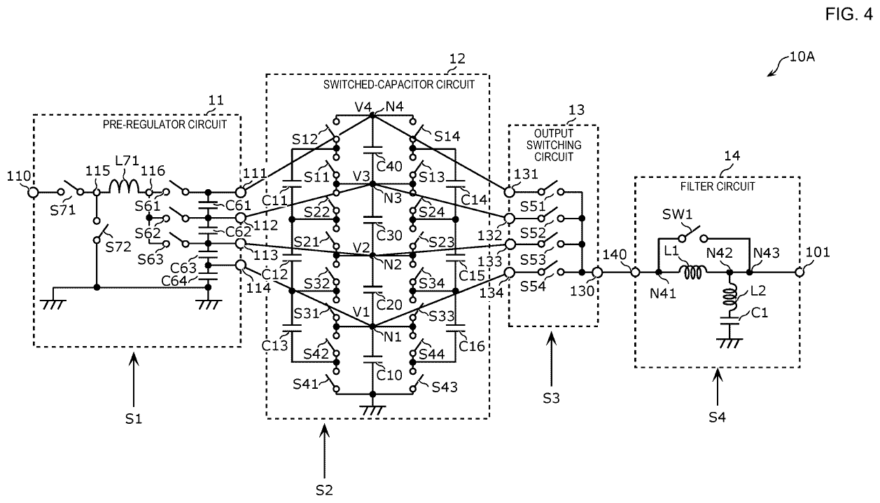

Next, circuit configuration of the pre-regulator circuit 11, the switched-capacitor circuit 12, the output switching circuit 13, and the filter circuit 14, which are included in the voltage supply circuit 10A, are described with reference to FIG. 4.

FIG. 4 is a diagram of circuit configurations of the pre-regulator circuit 11, the switched-capacitor circuit 12, the output switching circuit 13, and filter circuit 14 according to Example 1.

It is noted that FIG. 4 is an exemplary circuit configuration, and that the pre-regulator circuit 11, the switched-capacitor circuit 12, the output switching circuit 13, and the filter circuit 14may be implemented using any of a wide variety of circuit implementations or circuit technologies. Therefore, a description of each of the circuits to be provided below should not be interpreted in a limited manner.

### 2.1 Circuit Configuration of Switched-Capacitor Circuit 12

As illustrated in FIG. 4, the switched-capacitor circuit 12 includes capacitors C11 to C16, capacitors C10, C20, C30, and C40, and switches S11 to S14, S21 to S24, S31 to S34, and S41 to S44. Energy and electric charges are input from the pre-regulator circuit 11 to the switched-capacitor circuit 12 at nodes N1 to N4 and drawn from the switched-capacitor circuit 12 to the output switching circuit 13 at the nodes N1 to N4.

Each of the capacitors C11 to C16 can be configured to function as a flying capacitor (which may be referred to as a transfer capacitor) according to an exemplary aspect. That is, each of the capacitors C11 to C16 are used to step up or down input voltages supplied from the pre-regulator circuit 11. More specifically, the capacitors C11 to C16 transfer electric charges between the capacitors C11 to C16 and the nodes N1 to N4 so that voltages V1 to V4 (voltages with respect to a ground potential), which satisfy V1:V2:V3:V4=1:2:3:4 at the four nodes N1 to N4, are maintained. These voltages V1 to V4 correspond to a plurality of discrete voltages.

The capacitor C11 has two electrodes. One of the two electrodes of the capacitor C11 is connected to one end of the switch S11 and one end of the switch S12. The other of the two electrodes of the capacitor C11 is connected to one end of the switch S21 and one end of the switch S22.

The capacitor C12 has two electrodes. One of the two electrodes of the capacitor C12 is connected to the one end of the switch S21 and the one end of the switch S22. The other of the two electrodes of the capacitor C12 is connected to one end of the switch S31 and one end of the switch S32.

The capacitor C13 has two electrodes. One of the two electrodes of the capacitor C13 is connected to the one end of the switch S31 and one end of the switch S32. The other of the two electrodes of the capacitor C13 is connected to one end of the switch S41 and one end of the switch S42.

The capacitor C14 has two electrodes. One of the two electrodes of the capacitor C14 is connected to one end of the switch S13 and one end of the switch S14. The other of the two electrodes of the capacitor C14 is connected to one end of the switch S23 and one end of the switch S24.

The capacitor C15 has two electrodes. One of the two electrodes of the capacitor C15 is connected to the one end of the switch S23 and the one end of the switch S24. The other of the two electrodes of the capacitor C15 is connected to one end of the switch S33 and one end of the switch S34.

The capacitor C16 has two electrodes. One of the two electrodes of the capacitor C16 is connected to the one end of the switch S33 and the one end of the switch S34. The other of the two electrodes of the capacitor C16 is connected to one end of the switch S43 and one end of the switch S44.

Each of a set of the capacitors C11 and C14, a set of the capacitors C12 and C15, and a set of the capacitors C13 and C16 can perform charging and discharging in a complementary manner, with a first phase and a second phase being repeated.

Specifically, in the first phase, the switches S12, S13, S22, S23, S32, S33, S42, and S43 are turned ON. As a result, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

In contrast, in the second phase, the switches S11, S14, S21, S24, S31, S34, S41, and S44 are turned ON. As a result, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

Repetition of such first and second phases enables the other of the capacitor C12 and the other of the capacitor C15 to discharge to the capacitor C30, for example, while the one of the capacitor C12 and one of the capacitor C15 are being charged from the node N2. That is, the capacitors C12 and C15 can perform charging and discharging in a complementary manner.

Similarly to the set of the capacitors C12 and C15, the repetition of the first and second phases also enables each of the set of the capacitors C11 and C14 and the set of the capacitors C13 and C16 to perform charging and discharging in a complementary manner.

Each of the capacitors C10, C20, C30, and C40 can be configured to function as a smoothing capacitor. That is, each of the capacitors C10, C20, C30, and C40 is used to hold and smoothen the voltages V1 to V4 at the nodes N1 to N4.

The capacitor C10 is connected between the node N1 and the ground. Specifically, one of two electrodes of the capacitor C10 is connected to the node N1. Meanwhile, the other of the two electrodes of the capacitor C10 is connected to the ground.

The capacitor C20 is connected between the nodes N2 and N1. Specifically, one of two electrodes of the capacitor C20 is connected to the node N2. Meanwhile, the other of the two electrodes of the capacitor C20 is connected to the node N1.

The capacitor C30 is connected between the nodes N3 and N2. Specifically, one of two electrodes of the capacitor C30 is connected to the node N3. Meanwhile, the other of the two electrodes of the capacitor C30 is connected to the node N2.

The capacitor C40 is connected between the nodes N4 and N3. Specifically, one of two electrodes of the capacitor C40 is connected to the node N4. Meanwhile, the other of the two electrodes of the capacitor C40 is connected to the node N3.

The switch S11 is connected between the one of the two electrodes of the capacitor C11 and the node N3. Specifically, the one end of the switch S11 is connected to the one of the two electrodes of the capacitor C11. Meanwhile, another end of the switch S11 is connected to the node N3.

The switch S12 is connected between the one of the two electrodes of the capacitor C11 and the node N4. Specifically, the one end of the switch S12 is connected to the one of the two electrodes of the capacitor C11. Meanwhile, another end of the switch S12 is connected to the node N4.

The switch S21 is connected between the one of the two electrodes of the capacitor C12 and the node N2. Specifically, the one end of the switch S21 is connected to the one of the two electrodes of the capacitor C12 and the other of the two electrodes of the capacitor C11. Meanwhile, another end of the switch S21 is connected to the node N2.

The switch S22 is connected between the one of the two electrodes of the capacitor C12 and the node N3. Specifically, the one end of the switch S22 is connected to the one of the two electrodes of the capacitor C12 and the other of the two electrodes of the capacitor C11. Meanwhile, another end of the switch S22 is connected to the node N3.

The switch S31 is connected between the other of the two electrodes of the capacitor C12 and the node N1. Specifically, the one end of the switch S31 is connected to the other of the two electrodes of the capacitor C12 and the one of the two electrodes of the capacitor C13. Meanwhile, another end of the switch S31 is connected to the node N1.

The switch S32 is connected between the other of the two electrodes of the capacitor C12 and the node N2. Specifically, the one end of the switch S32 is connected to the other of the two electrodes of the capacitor C12 and the one of the two electrodes of the capacitor C13. Meanwhile, another end of the switch S32 is connected to the node N2. That is, the other end of the switch S32 is connected to the other end of the switch S21.

The switch S41 is connected between the other of the two electrodes of the capacitor C13 and the ground. Specifically, the one end of the switch S41 is connected to the other of the two electrodes of the capacitor C13. Meanwhile, another end of the switch S41 is connected to the ground.

The switch S42 is connected between the other of the two electrodes of the capacitor C13 and the node N1. Specifically, the one end of the switch S42 is connected to the other of the two electrodes of the capacitor C13. Meanwhile, another end of the switch S42 is connected to the node N1. That is, the other end of the switch S42 is connected to the other end of the switch S31.

The switch S13 is connected between the one of the two electrodes of the capacitor C14 and the node N3. Specifically, the one end of the switch S13 is connected to the one of the two electrodes of the capacitor C14. Meanwhile, another end of the switch S13 is connected to the node N3. That is, the other end of the switch S13 is connected to the other end of the switch S11 and the other end of the switch S22.

The switch S14 is connected between the one of the two electrodes of the capacitor C14 and the node N4. Specifically, the one end of the switch S14 is connected to the one of the two electrodes of the capacitor C14. Meanwhile, another end of the switch S14 is connected to the node N4. That is, the other end of the switch S14 is connected to the other end of the switch S12.

The switch S23 is connected between the one of the two electrodes of the capacitor C15 and the node N2. Specifically, the one end of the switch S23 is connected to the one of the two electrodes of the capacitor C15 and the other of the two electrodes of the capacitor C14. Meanwhile, another end of the switch S23 is connected to the node N2. That is, the other end of the switch S23 is connected to the other end of the switch S21 and the other end of the switch S32.

The switch S24 is connected between the one of the two electrodes of the capacitor C15 and the node N3. Specifically, the one end of the switch S24 is connected to the one of the two electrodes of the capacitor C15 and the other of the two electrodes of the capacitor C14. Meanwhile, another end of the switch S24 is connected to the node N3. That is, the other end of the switch S24 is connected to the other end of the switch S11, the other end of the switch S22, and the other end of the switch S13.

The switch S33 is connected between the other of the two electrodes of the capacitor C15 and the node N1. Specifically, the one end of the switch S33 is connected to the other of the two electrodes of the capacitor C15 and the one of the two electrodes of the capacitor C16. Meanwhile, another end of the switch S33 is connected to the node N1. That is, the other end of the switch S33 is connected to the other end of the switch S31 and the other end of the switch S42.

The switch S34 is connected between the other of the two electrodes of the capacitor C15 and the node N2. Specifically, the one end of the switch S34 is connected to the other of the two electrodes of the capacitor C15 and the one of the two electrodes of the capacitor C16. Meanwhile, another end of the switch S34 is connected to the node N2. That is, the other end of the switch S34 is connected to the other end of the switch S21, the other end of the switch S32, and the other end of the switch S23.

The switch S43 is connected between the other of the two electrodes of the capacitor C16 and the ground. Specifically, the one end of the switch S43 is connected to the other of the two electrodes of the capacitor C16. Meanwhile, another end of the switch S43 is connected to the ground.

The switch S44 is connected between the other of the two electrodes of the capacitor C16 and the node N1. Specifically, the one end of the switch S44 is connected to the other of the two electrodes of the capacitor C16. Meanwhile, another end of the switch S44 is connected to the node N1. That is, the other end of the switch S44 is connected to the other end of the switch S31, the other end of the switch S42, and the other end of the switch S33.

The switches S11, S12, S13, S14, S21, S22, S23, and S24 are each at least one switch included in the switched-capacitor circuit 12.

A first set of switches including the switches S12, S13, S22, S23, S32, S33, S42, and S43 and a second set of switches including the switches S11, S14, S21, S24, S31, S34, S41, and S44 are switched ON and OFF based on a control signal S2 in a complementary manner. Specifically, in the first phase, the first set of switches is turned ON and the second set of switches is turned OFF. Conversely, in the second phase, the first set of switches is turned OFF and the second set of switches is turned ON.

For example, in one of the first phase and the second phase, charging of the capacitors C10 to C40 is performed from the capacitors C11 to C13, and in the other of the first phase and the second phase, charging of the capacitors C10 to C40 is performed from the capacitors C14 to C16. That is, the capacitors C10 to C40 are constantly charged from the capacitors C11 to C13 or the capacitors C14 to C16. Therefore, even when electric currents flow from the nodes N1 to N4 to the output switching circuit 13 at a high speed, fluctuations in potentials of the nodes N1 to N4 can be suppressed because the nodes N1 to N4 are replenished with electric charges at a high speed.

By operating in this manner, the switched-capacitor circuit 12 can maintain an approximately equal voltage at both ends of each of the capacitors C10, C20, C30, and C40. Specifically, the voltages V1 to V4 (voltages relative to the ground potential) that satisfy V1:V2:V3:V4=1:2:3:4 are maintained at four nodes labelled V1 to V4. Voltage levels of the voltages V1 to V4 correspond to a plurality of discrete voltage levels that can be supplied by the switched-capacitor circuit 12 to the output switching circuit 13.

It is noted that a voltage ratio (V1:V2:V3:V4) is not limited to (1:2:3:4). For example, the voltage ratio (V1:V2:V3:V4) may be (1:2:4:8) in an alternative aspect.

In addition, a configuration of the switched-capacitor circuit 12 illustrated in FIG. 4 is merely an example, and is not limited thereto. In FIG. 4, the switched-capacitor circuit 12 is configured to be able to supply four discrete voltages, but the configuration is not limited thereto. The switched-capacitor circuit 12 may be configured to be able to supply voltages of any number of discrete voltage levels, which is 2 or more. For example, when supplying two discrete voltages, the switched-capacitor circuit 12 should include at least the capacitors C12 and C15 as well as the switches S21 to S24 and S31 to S34.

### 2.2 Circuit Configuration of Output Switching Circuit 13

As illustrated in FIG. 4, the output switching circuit 13 includes input terminals 131 to 134, switches S51 to S54, and an output terminal 130.

The output terminal 130 is connected to an input terminal 140 of the filter circuit 14. The output terminal 130 is a terminal for supplying a power supply voltage selected from the voltages V1 to V4 to the PA module 2 via the filter circuit 14.

The input terminals 131 to 134 are connected to the nodes N4 to N1 of the switched-capacitor circuit 12, respectively. The input terminals 131 to 134 are terminals for receiving the voltages V4 to V1 from the switched-capacitor circuit 12.

The switch S51 is connected between the input terminal 131 and the output terminal 130. Specifically, the switch S51 has a terminal connected to the input terminal 131 and a terminal connected to the output terminal 130. In this connection configuration, by being switched ON and OFF by a control signal S3, the switch S51 can switch between connection and disconnection between the input terminal 131 and the output terminal 130.

The switch S52 is connected between an input terminal 132 and the output terminal 130. Specifically, the switch S52 has a terminal connected to the input terminal 132 and a terminal connected to the output terminal 130. In this connection configuration, by being switched ON and OFF by a control signal S3, the switch S52 can switch between connection and disconnection between the input terminal 132 and the output terminal 130.

The switch S53 is connected between an input terminal 133 and the output terminal 130. Specifically, the switch S53 has a terminal connected to the input terminal 133 and a terminal connected to the output terminal 130. In this connection configuration, by being switched ON and OFF by a control signal S3, the switch S53 can switch between connection and disconnection between the input terminal 133 and the output terminal 130.

The switch S54 is connected between the input terminal 134 and the output terminal 130. Specifically, the switch S54 has a terminal connected to the input terminal 134 and a terminal connected to the output terminal 130. In this connection configuration, by being switched ON and OFF by a control signal S3, the switch S54 can switch between connection and disconnection between the input terminal 134 and the output terminal 130.

The switches S51 and S52 are each at least one switch included in the output switching circuit 13.

These switches S51 to S54 are controlled to be exclusively ON. That is, only one of the switches S51 to S54 is turned ON, and remaining switches of the switches S51 to S54 are turned OFF. This allows the output switching circuit 13 to output one voltage selected from the voltages V1 to V4.

It is noted that configuration of the output switching circuit 13 illustrated in FIG. 4 is merely example, and are not limited thereto. In particular, the switches S51 to S54 may have any configuration as long as they can selectively connect at least one of the four input terminals 131 to 134 to the output terminal 130. For example, the output switching circuit 13 may further include a switch that is connected between the switches S51 to S53 and the switches S54 and the output terminal 130. In addition, for example, the output switching circuit 13 may further include a switch connected between the switches S51 and S52, the Switches S53 and S54, and the output terminal 130.

It is noted that when two discrete voltages are supplied from the switched-capacitor circuit 12, the output switching circuit 13 should include at least two of the switches S51 to S54.

### 2.3 Circuit Configuration of Pre-regulator Circuit 11

As illustrated in FIG. 4, the pre-regulator circuit 11 includes an input terminal 110, output terminals 111 to 114, inductor connection terminals 115 and 116, switches S61 to S63, as well as S71 and S72, a power inductor L71, and capacitors C61 to C64.

The input terminal 110 is a direct current voltage input terminal for receiving an input voltage from a direct-current power supply.

The output terminal 111 is an output terminal for the voltage V4. That is, the output terminal 111 is a terminal for supplying the voltage V4 to the switched-capacitor circuit 12. The output terminal 111 is connected to the node N4 of the switched-capacitor circuit 12.

The output terminal 112 is an output terminal for the voltage V3. That is, the output terminal 112 is a terminal for supplying the voltage V3 to the switched-capacitor circuit 12. The output terminal 112 is connected to the node N3 of the switched-capacitor circuit 12.

The output terminal 113 is an output terminal for the voltage V2. That is, the output terminal 113 is a terminal for supplying the voltage V2 to the switched-capacitor circuit 12. The output terminal 113 is connected to the node N2 of the switched-capacitor circuit 12.

The output terminal 114 is an output terminal for the voltage V1. That is, the output terminal 114 is a terminal for supplying the voltage V1 to the switched-capacitor circuit 12. The output terminal 114 is connected to the node N1 of the switched-capacitor circuit 12.

The inductor connection terminal 115 is connected to one end of the power inductor L71. The inductor connection terminal 116 is connected to another end of the power inductor L71.

The switch S71 is connected between the input terminal 110 and the one end of the power inductor L71. Specifically, the switch S71 has a terminal connected to the input terminal 110 and a terminal connected to the one end of the power inductor L71 via the inductor connection terminal 115. In this connection configuration, by switching ON/OFF based on a control signal S1, the switch S71 can switch between connection and disconnection between the input terminal 110 and the one end of the power inductor L71.

The switch S72 is connected between the one end of the power inductor L71 and the ground. Specifically, the switch S72 has a terminal connected to the one end of the power inductor L71 via the inductor connection terminal 115, and a terminal connected to the ground. In this connection configuration, by switching ON/OFF based on the control signal S1, the switch S72 can switch between connection and disconnection between the one end of the power inductor L71 and the ground.

The switch S61 is connected between the other end of the power inductor L71 and the output terminal 111. Specifically, the switch S61 has a terminal connected to the other end of the power inductor L71 via the inductor connection terminal 116, and a terminal connected to the output terminal 111. In this connection configuration, by switching ON/OFF based on the control signal S1, the switch S61 can switch between connection and disconnection between the other end of the power inductor L71 and the output terminal 111.

A switch S62 is connected between the other end of the power inductor L71 and the output terminal 112. Specifically, the switch S62 has a terminal connected to the other end of the power inductor L71 via the inductor connection terminal 116, and a terminal connected to the output terminal 112. In this connection configuration, by switching ON/OFF based on the control signal S1, the switch S62 can switch between connection and disconnection between the other end of the power inductor L71 and the output terminal 112.

The switch S63 is connected between the other end of the power inductor L71 and the output terminal 113. Specifically, the switch S63 has a terminal connected to the other end of the power inductor L71 via the inductor connection terminal 116, and a terminal connected to the output terminal 113. In this connection configuration, by switching ON/OFF based on the control signal S1, the switch S63 can switch between connection and disconnection between the other end of the power inductor L71 and the output terminal 113.

The switches S71 and S72 are each at least one switch included in the pre-regulator circuit 11.

One of two electrodes of the capacitor C61 is connected to the switch S61 and the output terminal 111. The other of the two electrodes of the capacitor C61 is connected to the switch S62, the output terminal 112, and one of two electrodes of the capacitor C62. The capacitor C61 can be configured to function as a smoothing capacitor.

The one of the two electrodes of the capacitor C62 is connected to the switch S62, the output terminal 112, and the other of the two electrodes of the capacitor C61. The other of the two electrodes of the capacitor C62 is connected to the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to the ground.

The switches S61 to S63 are controlled to be exclusively ON. That is, only one of the switches S61 to S63 is turned ON, and remaining switches of the switches S61 to S63 are turned OFF. By turning ON only one of the switches S61 to S63, the pre-regulator circuit 11 can change a voltage to be supplied to the switched-capacitor circuit 12 at the voltage levels of the voltages V2 to V4.

The pre-regulator circuit 11 configured in this manner can supply electric charges to the switched-capacitor circuit 12 via at least one of the output terminals 111 to 113.

It is noted that when an input voltage to the pre-regulator circuit 11 is converted to one voltage in an exemplary aspect, the pre-regulator circuit 11 should include at least the switches S71 and S72, and the power inductor L71.

### 2.4 Circuit Configuration of Filter Circuit 14

As illustrated in FIG. 4, the filter circuit 14 includes inductors L1 and L2, a capacitor C1, a switch SW1, the input terminal 140, and the external output terminal 101.

The input terminal 140 is connected to the output terminal 130 of the output switching circuit 13. The input terminal 140 is a terminal for receiving a voltage selected from a plurality of discrete voltages by the output switching circuit 13.

The external output terminal 101 is an external connection terminal of the ET module 1A and is connected to the PA module 2. The external output terminal 101 is a terminal for supplying the PA module 2 with the power supply voltage V_{ET} which is a plurality of discrete voltages that have passed through the filter circuit 14.

The inductor L1 is connected between the input terminal 140 and the external output terminal 101. That is, the inductor L1 is disposed in series in a path connecting the input terminal 140 and the external output terminal 101. Specifically, one end of the inductor L1 is connected to the input terminal 140, and another end of the inductor L1 is connected to the external output terminal 101.

The inductor L2 is connected between a path connecting between the inductor L1 and the external output terminal 101, and the ground. That is, the inductor L2 is shunt-connected to the path connecting the input terminal 140 and the external output terminal 101. Specifically, one end of the inductor L2 is connected to a node N42 on the path connecting the inductor L1 and the external output terminal 101, and another end of the inductor L2 is connected to the ground via the capacitor C1. It is noted that the inductor L2 may be connected between the capacitor C1 and the ground, and may not be included in the filter circuit 14 in an exemplary aspect.

The capacitor C1 is connected between the inductor L2 and the ground. That is, the capacitor C1 is shunt-connected to the path connecting the input terminal 140 and the external output terminal 101. Specifically, one end of the capacitor C1 is connected to the inductor L2 and another end of the capacitor C1 is connected to the ground.

The switch SW1 is connected between the input terminal 140 and the external output terminal 101 not via the inductor L1. That is, the switch SW1 is disposed in series in a path that bypasses the inductor L1 between the input terminal 140 and the external output terminal 101. Specifically, one end of the switch SW1 is connected to a node N41 on a path connecting the input terminal 140 and the inductor L1, and another end of the switch SW1 is connected to a node N43 on the path connecting the inductor L1 and the external output terminal 101.

It is noted that in FIG. 4, the switch SW1 and the inductor L1 are connected in parallel, but another circuit element may be inserted in a path of the switch SW1 and/or a path of the inductor L1 in an exemplary aspect. For example, an inductor may be connected between the switch SW1 and the node N43 and/or between the switch SW1 and the node N41.

In addition, in FIG. 4, although the node N43 to which the other end of the switch SW1 is connected is located between the node N42 to which the inductor L2 is connected and the external output terminal 101, a positional relationship between the node N42 and the node N43 is not limited thereto. For example, the node N42 may be located between the node N43 and the external output terminal 101. In addition, for example, a position of the node N42 may be the same as that of the node N43.

The switch SW1 connected in this manner is switched ON/OFF based on a control signal S4. This allows the filter circuit 14 to switch ON/OFF a band-stop filter for removing noise from a plurality of discrete voltages.

ON/OFF of such a band-stop filter can be controlled based on, for example, a channel band width (i.e., modulation band width) of a radio frequency signal RFA. In addition, when the PA module 2 is configured to amplify transmission signals of a plurality of frequency bands, the ON/OFF of the switch SW1 may be controlled based on the frequency bands of the transmission signals amplified by the PA module 2. It is noted that control of the band-stop filter is not limited to the above.

### 3. Circuit Configuration of ET Module 1B and Communication Device 5B in Example 2

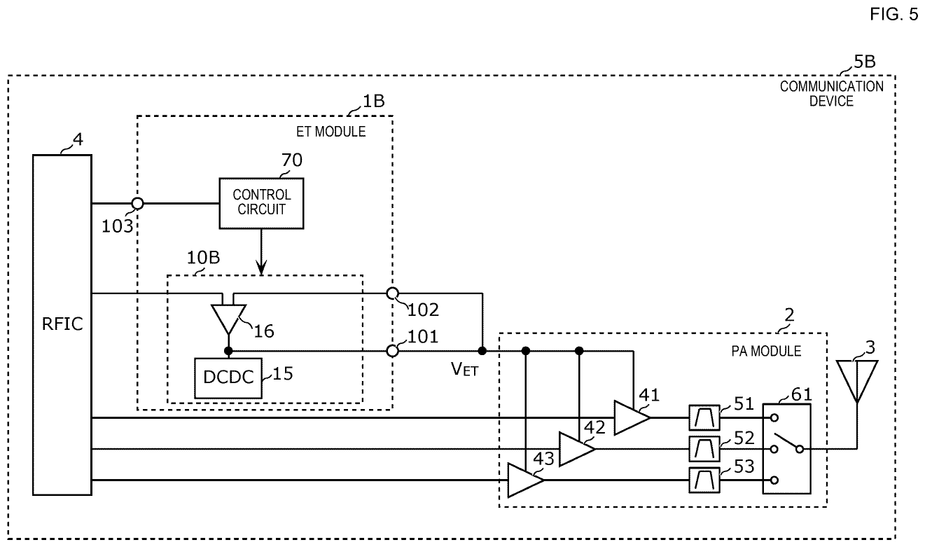

FIG. 5 is a circuit configuration diagram of an ET module 1B and a communication device 5B according to Example 2. The ET module 1B and the communication device 5B according to this Example are examples of the ET module 1 and the communication device 5 according to the present embodiment, and illustrate a specific example of the circuit configuration of the ET module 1.

The communication device 5B according to this Example includes the ET module 1B, the PA module 2, the antenna 3, and the RFIC 4. The communication device 5B according to this Example differs from the communication device 5 according to the embodiment in the configuration of the ET module 1B. Therefore, in the following, the communication device 5B according to this Example is mainly described with a focus on the configuration of the ET module 1B.

The ET module 1B is an example of a tracker module, and can supply the power supply voltage VET, the voltage levels of which vary, to the PA module 2, based on a tracking mode. The analog ET mode and the APT mode can be used as a tracking mode, but the tracking mode is not limited thereto. As illustrated in FIG. 5, the ET module 1B includes a voltage supply circuit 10B, the control circuit 70, the external output terminal 101, the external input terminal 102, and the control signal terminal 103. The ET module 1B according to this Example differs from the ET module 1 according to the embodiment in a configuration of the voltage supply circuit 10B. In the following, the ET module 1B according to this Example is described, omitting the same configurations as those of the ET module 1 according to the embodiment and focusing on different configurations.

The voltage supply circuit 10B includes DC-DC converter 15 and linear amplifier circuit 16.

The DC-DC converters 15 has, for example, one power inductor and outputs a direct-current voltage. It is noted that based on a control signal received from the control circuit 70, the DC-DC converter 15 can change a level of the direct current voltage for each symbol or for average electric power corresponding to the DC-DC converter 15.

The linear amplifier circuit 16 receives, from the RFIC 4, an envelope signal representative of a power supply voltage waveform based on an envelope value, and linearly amplifies the envelope signal.

In operation, when the analog ET mode is applied to the ET module 1B, for example, the linear amplifier circuit 16 are operated, and the power supply voltage V_{ET}, which corresponds to an envelope value and the voltage levels of which vary, are generated at the voltage supply circuit 10B. The voltage supply voltage V_{ET} is supplied to the PA module 2 via the external output terminal 101. In addition, when the APT mode is applied to the ET module 1B, for example, the linear amplifier circuit 16 is not operated, and the power supply voltage V_{ET}, which is stabilized, is generated at the voltage supply circuit 10B. The voltage supply voltage V_{ET} is supplied to the PA module 2 via the external output terminal 101.

### 4. Implementation Examples of ET Module 1A According to Example 1

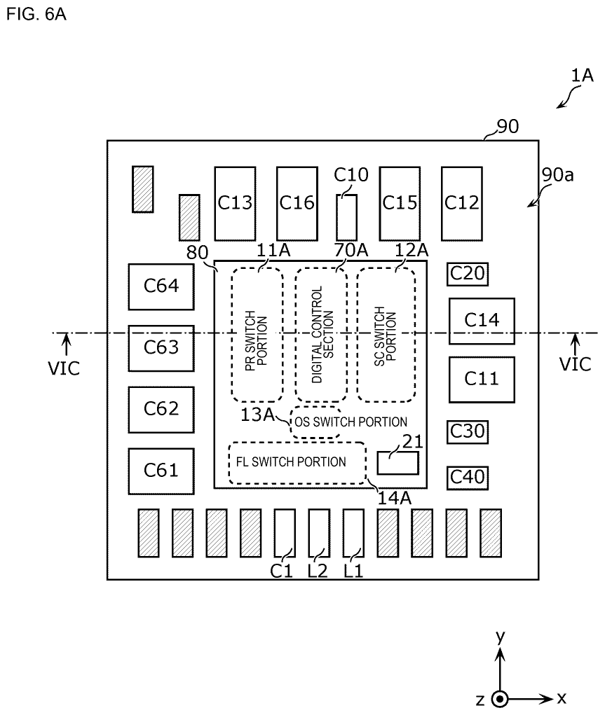

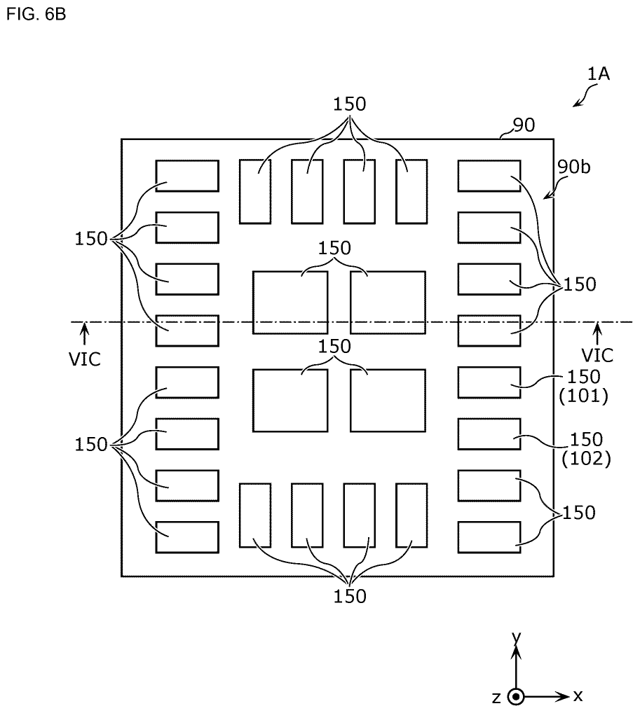

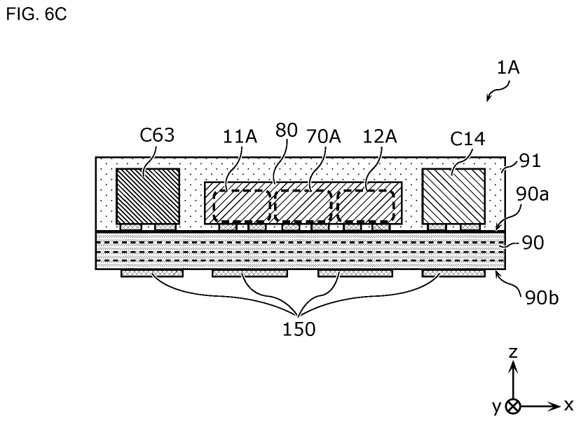

Next, as an implementation example of the ET module 1 configured as described above, an implementation configuration of the ET module 1A according to Example 1 is described with reference to FIGS. 6A to 6C.

It is noted that in this Example, the power inductor L71 included in the pre-regulator circuit 11 is not disposed on a module laminate 90, but is not limited thereto. That is, the power inductor L71 may be disposed on the module laminate 90.

FIG. 6A is a plan view of the ET module 1A according to Example 1. FIG. 6B is a plan view of the ET module 1A according to Example 1. FIG. 6A is a view of a main surface 90a side of the module laminate 90 viewed from the z-axis positive side. FIG. 6B is a perspective view of a main surface 90b side of the module laminate 90 from the z-axis positive side. FIG. 6C a cross-sectional view of the ET module 1A according to Example 1. A cross section of the ET module 1A in FIG. 6C is a cross section taken along VIC-VIC line in FIGS. 6A and 6B.

It is noted that in FIGS. 6A to 6C, illustration of some of wiring lines connecting a plurality of circuit components disposed on the module laminate 90 is omitted. In FIGS. 6A and 6B, illustration of a resin member 91 covering the plurality of circuit components is omitted. Furthermore, in FIG. 6C, illustration of a shield electrode layer covering the resin member 91 is omitted. It is noted that the resin member 91 and the shield electrode layer may be omitted in an exemplary aspect. In addition, hatched blocks in FIG. 6A represent optional circuit components that may be omitted in an exemplary aspect.

As illustrated in FIGS. 6A and 6B, the ET module 1A includes the module laminate 90, an integrated circuit 80, the external output terminal 101 and the external input terminal 102.

The module laminate 90 has the main surfaces 90a and 90b that face each other. A ground plane or the like is formed in the module laminate 90 and on the main surface 90a. It is noted that although the module laminate 90 has a rectangular shape in plan view in FIGS. 6A and 6B, the shape of the module laminate 90 is not limited thereto and be other shapes as would be appreciated to one skilled in the art.

The module laminate 90 may be, but is not limited to, for example, a low temperature co-fired ceramics (LTCC: Low Temperature Co-fired Ceramics) board or a high temperature co-fired ceramics (HTCC: High Temperature Co-fired Ceramics) board, which have a laminated structure of a plurality of dielectric layers, a component-embedded board, a board having a redistribution layer (RDL: Redistribution Layer), or a printed circuit board, or the like.

The integrated circuit 80 is disposed on the main surface 90a of the module laminate 90, and has a PR switch portion 11A, an SC switch portion 12A, an OS switch portion 13A, an FL switch portion 14A, and a digital control section 70A. The PR switch portion 11A includes the switches S61 to S63, S71, and S72 of the pre-regulator circuit 11. The SC switch portion 12A includes the switches S11 to S14, S21 to S24, S31 to S34, and S41 to S44 of the switched-capacitor circuit 12. The OS switch portion 13A includes the switches S51A to S54A of the output switching circuit 13. The FL switch portion 14A includes the switch SW1 of the filter circuit 14A. The digital control section 70A includes the control circuit 70.

In addition, in FIG. 6A, the integrated circuit 80 has a rectangular shape in plan view of the module laminate 90, but the shape of the integrated circuit 80 is not limited thereto.

The integrated circuit 80 includes, for example, a CMOS (Complementary Metal Oxide Semiconductor), and, specifically, may be manufactured by an SOI (Silicon on Insulator) process. It is noted that the integrated circuit 80 is not limited to a CMOS in alternative exemplary aspects.

It is noted that the integrated circuit 80 is not necessarily configured by, for example, a single chip, and may be configured by a plurality of chips. In addition, the integrated circuit 80 should include at least the SC switch portion 12A and the OS switch portion 13A, and the PR switch portion 11A, the FL switch portion 14A, and the digital control section 70A may be disposed outside of the integrated circuit 80.

Furthermore, as illustrated in FIG. 6B, a plurality of external connection terminals 150 is disposed on the main surface 90B. The plurality of external connection terminals 150 is electrically connected to a plurality of electronic components disposed on the main surface 90a via a via conductor or the like formed in the module laminate 90. The plurality of external connection terminals 150 may be a copper electrode but is not limited thereto. For example, a solder electrode may be used as the plurality of external connection terminals 150.

The external output terminal 101 is one of the plurality of external connection terminals 150, and the external input terminal 102 is another one of the plurality of external connection terminals 150. Some of the plurality of external connection terminals 150 other than the external output terminal 101 and the external input terminal 102 are set to the ground.

Here, the external output terminal 101 and the external input terminal 102 are adjacently disposed.

The external output terminal 101 is connected to the PA module 2, and the external input terminal 102 is connected to a node on the first path connecting the external output terminal 101 and the PA module 2. In contrast to this, according to an arrangement configuration of the external output terminal 101 and the external input terminal 102, since the external output terminal 101 and the external input terminal 102 are adjacently disposed, it is possible to reduce a total wiring length of a wiring line connecting the external output terminal 101 and the PA module 2 and a wiring line connecting the external input terminal 102 and the PA module 2. Therefore, waveform distortion of the power supply voltage V_{ET} output from the ET module 1A can be suppressed, thereby suppressing efficiency deterioration.

Furthermore, in addition to the ET module 1A includes the module laminate 90, the integrated circuit 80, and a plurality of the external connection terminals 150, the ET module 1A includes the capacitors C61 to C64 included in the pre-regulator circuit 11, the capacitors C11 to C16 and the capacitors C10 to C40 included in the switched-capacitor circuit 12, the inductors L1 and L2 as well as the capacitor C1 included in the filter circuit 14, and the resin member 91.

The integrated circuit 80, the capacitors C61 to C64, the capacitors C11 to C16, the capacitors C10 to C40, the inductors L1 and L2, the capacitor C1, and the resin member 91 are disposed on the main surface 90a.

The resin member 91 covers at least some of the plurality of electronic components on the main surface 90a. The resin member 91 has a function to ensure reliability such as mechanical strength and moisture resistance or the like of the plurality of electronic components on the main surface 90a. It is noted that the resin member 91 may be omitted from the ET module 1A in an exemplary aspect.

Each of the capacitors C61 to C64, the capacitors C11 to C16, and the capacitors C10 to C40 is implemented as a chip capacitor. In the exemplary aspect, a chip capacitor can refer to a surface mount device (SMD: Surface Mount Device) that forms a capacitor. It is noted that the implementation of a plurality of the capacitors is not limited to a chip capacitor. For example, some or all of the plurality of capacitors may be included in an integrated passive device (IPD: Integrated Passive Device) or may be included in the integrated circuit 80 in various exemplary aspects.

The inductors L1 and L2 are implemented as chip inductors. It is noted that a chip inductor can refer to an SMD that forms an inductor. It is also noted that the implementation of the inductors L1 and L2 is not limited to a chip inductor. For example, some or all of the inductors L1 and L2 may be included in an IPD in alternative aspects.

The plurality of capacitors and inductors disposed in this manner on the main surface 90a is grouped for each circuit and is disposed around the integrated circuit 80.

Specifically, a group of the capacitors C61 to C64 included in the pre-regulator circuit 11 is disposed in a region on the main surface 90a sandwiched between a straight line along a left edge of the integrated circuit 80 and a straight line along a left edge of the module laminate 90 in plan view of the module laminate 90. As a result, a group of circuit components included in the pre-regulator circuit 11 is disposed close to the PR switch portion 11A in the integrated circuit 80.

In plan view of the module laminate 90, a group of the capacitors C11 to C16 and the capacitors C10 to C40 included in the switched-capacitor circuit 12 is disposed in a region on the main surface 90a sandwiched between a straight line along an upper edge of the integrated circuit 80 and a straight line along an upper edge of the module laminate 90, as well as in a region on the main surface 90a sandwiched between a straight line along a right edge of the integrated circuit 80 and a straight line along a right edge of the module laminate 90. As a result, a group of circuit components included in the switched-capacitor circuit 12 is disposed close to the SC switch portion 12A of the integrated circuit 80. That is, the SC switch portion 12A is disposed closer to the capacitors C11 to C16 and the capacitors C10 to C40 of the switched-capacitor circuit 12 than each of the PR switch portion 11A and the OS switch portion 13A is.

In plan view of the module laminate 90, a group of the inductors L1 and L2 and the capacitor C1 included in the filter circuit 14 is disposed in a region on the main surface 90a sandwiched between a straight line along a lower edge of the integrated circuit 80 and a straight line along a lower edge of the module laminate 90. As a result, a group of circuit components included in the filter circuit 14 is disposed close to the FL switch portion 14A in the integrated circuit 80. That is, the FL switch portion 14A is disposed closer to the inductors L1 and L2 and the capacitor C1 of the filter circuit 14 than each of the PR switch portion 11A and the SC switch portion 12A is.

It is noted that configurations of the ET module 1A illustrated in FIGS. 6A to 6C are merely examples, and are not limited thereto. For example, some of the capacitors and the inductors disposed on the main surface 90a may be formed within the module laminate 90. In addition, some of the capacitors and the inductors disposed on the main surface 90a may be omitted from the ET module 1A and are not disposed on the module laminate 90.

### 5. Arrangement of ET Module 1A and Communication Device 5A According to Example 1

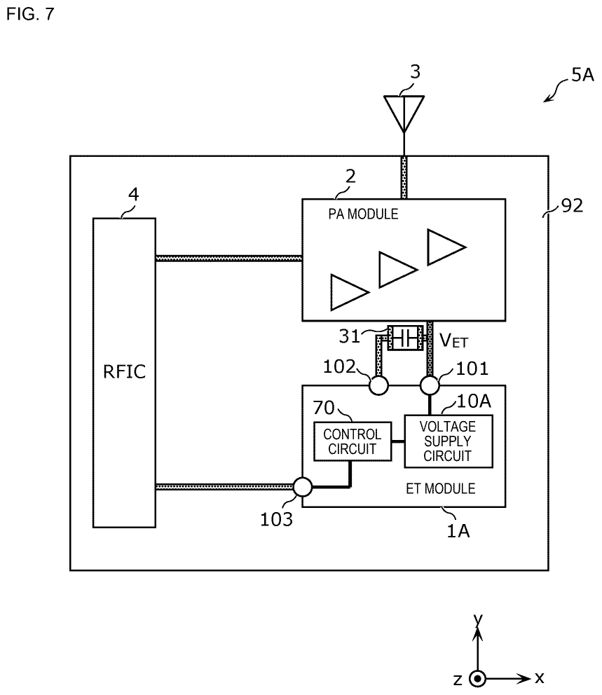

Next, a description is given of the arrangement on a motherboard 92 of the communication device 5A according to Example 1 with reference to FIG. 7. FIG. 7 is a plan view of the communication device 5A according to Example 1. As illustrated in FIG. 7, the communication device 5A includes the motherboard 92, the RFIC 4, the ET module 1A, the PA module 2, and the capacitor 31. The PA module 2 includes the power amplifiers 41 to 43.

The motherboard 92 can be, but is not limited to, for example, a printed circuit board, an LTCC board or an HTCC board, which have a laminated structure of a plurality of dielectric layers, a component-embedded board, a board having an RDL, or the like.

The RFIC 4, the ET module 1A, the PA module 2, and the capacitor 31 are disposed on a main surface of the motherboard 92.

The capacitor 31 is disposed on the motherboard 92 between the ET module 1A and the PA module 2. The capacitor 31 is connected between a node on the first path connecting the external output terminal 101 and the PA module 2, and the external input terminal 102. The capacitor 31 is implemented as a chip capacitor. It is noted that the capacitor 31 is not limited to a chip capacitor, and may be included in an IPD, or may be formed of a planar electrode in the motherboard 92 in an exemplary aspect.

The external output terminal 101 and the external input terminal 102 are adjacently disposed. This can reduce the total wiring length of the wiring line connecting the external output terminal 101 and the PA module 2 and the wiring line connecting the external input terminal 102 and the PA module 2. Therefore, the waveform distortion of the power supply voltage V_{ET} output from the ET module 1A can be suppressed, thereby suppressing the efficiency deterioration.

In addition, the external output terminal 101 and the external input terminal 102 are connected to the capacitor 31. As a result of this configuration, when the APT mode is applied to the ET module 1A, the capacitor 31 can be configured to function as the bypass condenser, and the voltage level of the power supply voltage V_{ET} can be stabilized.

### 6. Arrangement of ET module 1B and Communication Device 5B According to Example 2

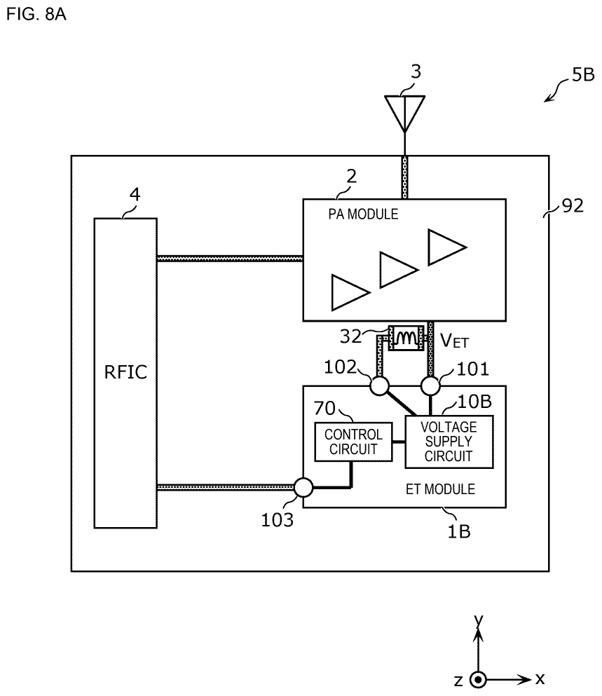

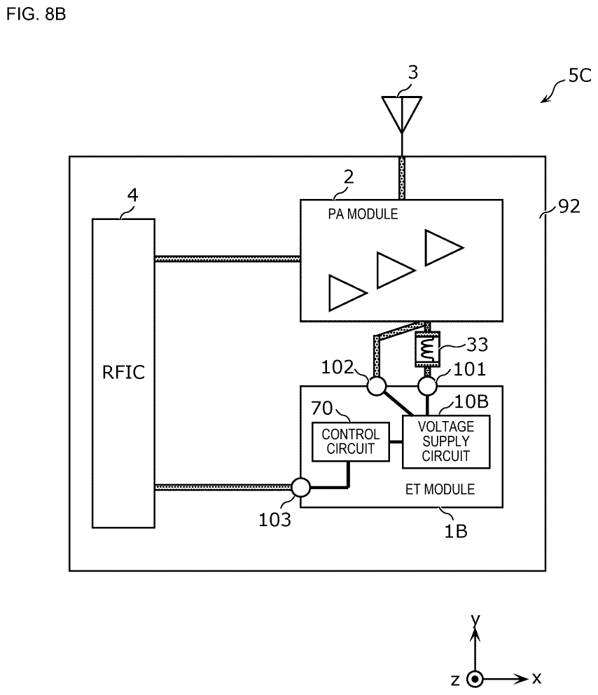

Next, a description is given of the arrangement on the motherboard 92 of the communication device 5B according to Example 2 with reference to FIG. 8A. FIG. 8A is a plan view of the communication device 5B according to Example 2. As illustrated in FIG. 8A, the communication device 5B includes the motherboard 92, the RFIC 4, the ET module 1B, the PA module 2, and inductor 32. The PA module 2 includes the power amplifiers 41 to 43. It is noted that as compared to the circuit configuration of the communication device 5B illustrated in FIG. 5, the inductor 32 is added to the communication device 5B illustrated in FIG. 8A. An implementation configuration of the communication device 5B illustrated in FIG. 8A mainly differs from that of the communication device 5A illustrated in FIG. 7 in that inductor 32 is disposed instead of the capacitor 31. In the following, the implementation configuration of the communication device 5B according to Example 2 is described with a focus on different points from the implementation configuration of the communication device 5A according to Example 1, and a description of the same points is omitted.

The RFIC 4, the ET module 1B, the PA module 2, and the inductor 32 are disposed on the main surface of the motherboard 92.

The inductor 32 is disposed on the motherboard 92 between the ET module 1B and the PA module 2. The inductor 32 is connected between the node on the first path connecting the external output terminal 101 and the PA module 2, and the external input terminal 102. The inductor 32 is implemented as a chip inductor. It is noted that the inductor 32 is not limited to the chip inductor, and may be included in an IPD or may be formed of a planar coil in the motherboard 92 in exemplary aspects.

The external output terminal 101 and the external input terminal 102 are adjacently disposed. This can reduce the total wiring length of the wiring line connecting the external output terminal 101 and the PA module 2 and the wiring line connecting the external input terminal 102 and the PA module 2. Therefore, the waveform distortion of the power supply voltage V_{ET} output from the ET module 1B can be suppressed, thereby suppressing the efficiency deterioration.

In addition, the external input terminal 102 is connected to the voltage supply circuit 10B. This configuration makes it possible to return the feedback signal of the power supply voltage V_{ET} on the first path to the voltage supply circuit 10B via the external input terminal 102. It is noted that the external input terminal 102 may be connected to the control circuit 70, rather than being connected to the voltage supply circuit 10B.

In addition, the inductor 32 is connected between the external input terminal 102 and the node on the first path. As a result of this configuration, when the analog ET mode is applied to the ET module 1B, the inductor 32 can be configured to function as a choke coil that blocks a radio frequency signal leaking from the PA module 2. Therefore, it is possible to return the feedback signal of the power supply voltage V_{ET} on the first path to the ET module 1B with high precision via the external input terminal 102.

### 7. Arrangement of ET module 1B and Communication Device 5C According to Modification Example 1

Next, a description is given of the arrangement on the motherboard 92 of the communication device 5C according to Modification Example 1 with reference to FIG. 8B. FIG. 8B is a plan view of the communication device 5C according to Modification Example 1. As illustrated in FIG. 8B, the communication device 5C includes the motherboard 92, the RFIC 4, the ET module 1B, the PA module 2, and an inductor 33. The PA module 2 includes the power amplifiers 41 to 43. It is noted that as compared to the circuit configuration of the communication device 5B illustrated in FIG. 8A, instead of the inductor 32, the inductors 33 is disposed in the communication device 5C illustrated in FIG. 8B. In the following, an implementation configuration of the communication device 5C according to Modification Example 1 is described with a focus on different points from the implementation configuration of the communication device 5B according to Example 2, and a description of the same points is omitted.

The RFIC 4, the ET module 1B, the PA module 2, and the inductor 33 are disposed on the main surface of the motherboard 92.

The inductor 33 is disposed on the motherboard 92 between the ET module 1B and the PA module 2. The inductor 33 is disposed in series on the first path connecting the external output terminal 101 and the PA module 2. The inductor 33 is implemented as a chip inductor. However, the inductor 33 is not limited to chip inductors, and may be included in an IPD or may be formed of a planar coil in the motherboard 92.

The external output terminal 101 and the external input terminal 102 are adjacently disposed. This can reduce the total wiring length of the wiring line connecting the external output terminal 101 and the PA module 2 and the wiring line connecting the external input terminal 102 and the PA module 2. Therefore, the waveform distortion of the power supply voltage V_{ET} output from the ET module 1B can be suppressed, thereby suppressing the efficiency deterioration.

In addition, the inductor 33 is disposed in series on the first path connecting the external output terminal 101 and the PA module 2. As a result of this configuration, when the analog ET mode is applied to the ET module 1B, the inductor 33 can be configured to function as the choke coil that blocks a radio frequency signal leaking from the PA module 2. Therefore, superimposition of radio frequency noise on the power supply voltage V_{ET} output from the external output terminal 101 can be suppressed.

### 8. Circuit Configuration of ET Module 1D and Communication Device 5D According to Example 3

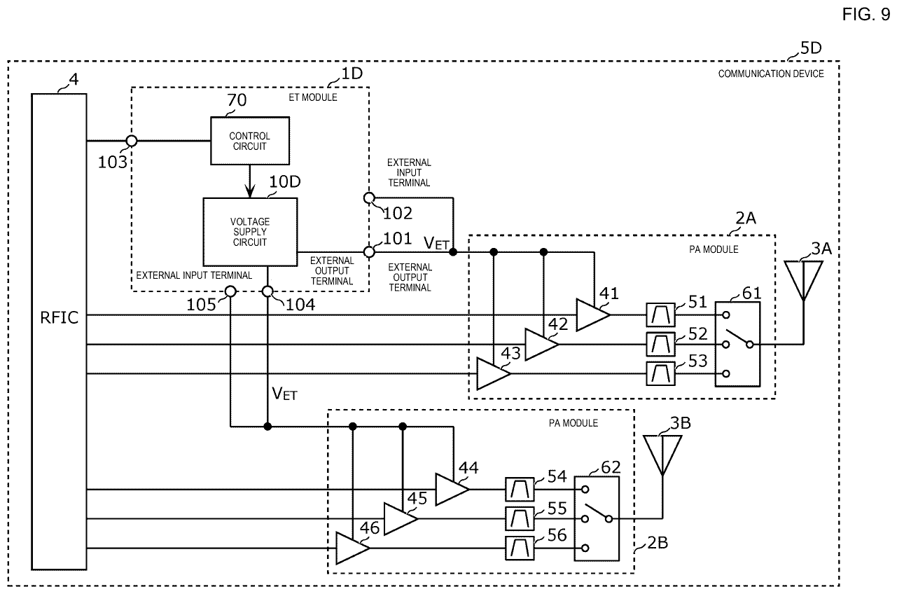

FIG. 9 is a circuit configuration diagram of an ET module 1D and a communication device 5D according to Example 3. As illustrated in FIG. 9, the communication device 5D according to this Example includes the ET module 1D, PA modules 2A and 2B, antennae 3A and 3B, and the RFIC 4. The communication device 5D according to this Example differs from the communication device 5 according to the embodiment in that the two PA modules are disposed and that a configuration of the ET module 1D is different. In the following, the communication device 5D according to Example 3 is described, omitting the same configurations as those of the communication device 5 according to the embodiment and focusing on different configurations.

The antenna 3A is connected to the PA module 2A and transmits a radio frequency signal output from the PA module 2A. The antenna 3B is connected to the PA module 2B and transmits a radio frequency signal output from the PA module 2B.

The ET module 1D supplies a power supply voltage V_{ET} to the PA modules 2A and 2B. The power supply voltage V_{ET} is an example of a voltage based on an envelope signal. The ET module 1D can supply the power supply voltage V_{ET} to the PA modules 2A and 2B in at least any of the APT mode, the analog ET mode, and the digital ET mode illustrated in FIGS. 1A to 1C.

As illustrated in FIG. 9, the ET module 1D includes a voltage supply circuit 10D, a control circuit 70, external output terminals 101 and 104, external input terminals 102 and 105, and control signal terminal 103.

The voltage supply circuit 10D is configured to supply the power supply voltage V_{ET} based on the envelope signal to the PA module 2A through the external output terminal 101, and to the PA module 2B through the external output terminal 104. Specifically, the voltage supply circuit 10D receives a control signal output from the control circuit 70 to generate the power supply voltage V_{ET}, and outputs the power supply voltage V_{ET} to the external output terminals 101 and 104.

The external output terminal 101 is an example of a first external output terminal that can be connected externally, and is connected to the voltage supply circuit 10D and the PA module 2A. The power supply voltage V_{ET}, which is generated by the voltage supply circuit 10D, is applied to the external output terminal 101.

The external input terminal 102 is an example of a first external input terminal that can be connected externally and is connected to a first path connecting the external output terminal 101 and the PA module 2A. In operation, when the analog ET mode is applied to the ET module 1D, the external input terminal 102 can be configured to function as a terminal for feeding back the power supply voltage V_{ET} on the first path to the ET module 1D, and is connected to the voltage supply circuit 10D or the control circuit 70 within the ET module 1D. In addition, when the APT mode is applied to the ET module 1D, the external input terminal 102 can be configured to function as a terminal for stabilizing the power supply voltage V_{ET} on the first path, and is connected to a capacitor, for example.

The external output terminal 104 is an example of a second external output terminal that can be connected externally and is connected to the voltage supply circuit 10D and the PA module 2B. The power supply voltage V_{ET}, which is generated by the voltage supply circuit 10D, is applied to the external output terminal 104.

The external input terminal 105 is an example of a second external input terminal that can be connected externally and is connected to a second path connecting the external output terminal 104 and the PA module 2B. In operation, when the analog ET mode is applied to the ET module 1D, the external input terminal 105 can be configured to function as a terminal for feeding back the power supply voltage V_{ET} on the second path to the ET module 1D, and is connected to the voltage supply circuit 10D or the control circuit 70 within the ET module 1D. In addition, when the APT mode is applied to the ET module 1D, the external input terminal 105 can be configured to function as a terminal for stabilizing the power supply voltage V_{ET} on the second path, and is connected to a capacitor, for example.

The PA module 2B receives supply of the power supply voltage V_{ET} from the ET module 1D, amplifies a radio frequency transmission signal input from the RFIC 4, and outputs the amplified radio frequency transmission signal to the antenna 3B. The PA module 2B includes power amplifiers 44, 45 and 46, filters 54, 55, and 56, and a switch 62.

Each of the power amplifiers 44 to 46 is connected between the ET module 1D and the antenna 3B. Specifically, a supply terminal of the power amplifier 44 is connected to the ET module 1D, a radio frequency input terminal is connected to the RFIC 4, and a radio frequency output terminal is connected to the antenna 3B via the filter 54 and the switch 62. A supply terminal of the power amplifier 45 is connected to the ET module 1D, a radio frequency input terminal is connected to the RFIC 4, and a radio frequency output terminal is connected to the antenna 3B via the filter 55 and the switch 62. A supply terminal of the power amplifier 46 is connected to the ET module 1D, a radio frequency input terminal is connected to the RFIC 4, and a radio frequency output terminal is connected to the antenna 3B via the filter 56 and the switch 62. The power amplifier 44 can amplify a radio frequency signal of band D, the power amplifier 45 can amplify a radio frequency signal of band E, and the power amplifier 46 can amplify a radio frequency signal of band F.

The filter 54 includes the band D as a pass band, for example. The filter 55 includes the band E as a pass band, for example. The filter 56 includes the band F as a pass band, for example.

The switch 62 has a common terminal and three selection terminals, and switches connection between the common terminal and any one of the three selection terminals. The common terminal of the switch 62 is connected to the antenna 3B, a first selection terminal is connected to the filter 54, a second selection terminal is connected to the filter 55, and a third selection terminal is connected to the filter 56.

According to configurations of the PA modules 2A and 2B described above, it is possible to amplify a radio frequency signal of any one of the band A, the band B, and the band C and output the amplified signal to the antenna 3A, and to amplify a radio frequency signal of any one of the band D, the band E, and the band F and output the amplified signal to the antenna 3B.

The node on the first path connecting each supply terminal of the power amplifiers 41 to 43 and the external output terminal 101 is connected to the external input terminal 102. In addition, a node on a second path connecting each supply terminal of the power amplifiers 44 to 46 and the external output terminal 104 is connected to the external input terminal 105.

According to the above-described configuration, the communication device 5D can simultaneously transmit a radio frequency signal of any of the band A to the band C and a radio frequency signal of any of the band D to the band F. In order to cope with this, the ET module 1D is configured to supply the power supply voltage V_{ET} (a first voltage) based on the envelope signal to the PA module 2A via the external output terminal 101, and simultaneously supply the power supply voltage V_{ET} (a second voltage) based on the envelope signal to the PA module 2B via the external output terminal 104.

### 9. ET Module 1D and Communication Device 5D According to Example 3

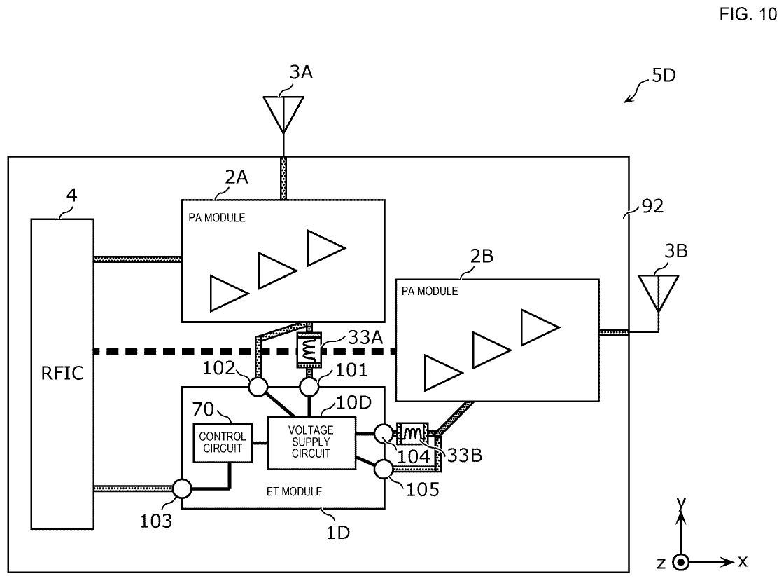

Next, a description is given of the arrangement on the motherboard 92 of the communication device 5D according to Example 3 with reference to FIG. 10. FIG. 10 is a plan view of the communication device 5D according to Example 3. As illustrated in FIG. 10, the communication device 5D includes the motherboard 92, the RFIC 4, the ET module 1D, the PA modules 2A and 2B, and inductors 33A and 33B. The PA module 2A includes the power amplifiers 41 to 43, and the PA module 2B includes the power amplifiers 44 to 46. It is noted that as compared to the circuit configuration of the communication device 5D illustrated in FIG. 9, the inductors 33A and 33B are added to the communication device 5D illustrated in FIG. 10. The communication device 5D according to this Example mainly differs from the communication device 5C according to Example 1 in that the two PA modules are disposed and that the two inductors are disposed. In the following, an implementation configuration of the communication device 5D according to Example 3 is described, with a focus on different points from the implementation configuration of the communication device 5C according to Example 1, and a description of the same points is omitted.

The RFIC 4, the ET module 1D, the PA modules 2A and 2B, and the inductors 33A and 33B are disposed on the main surface of the motherboard 92.

The inductor 33A is disposed on the motherboard 92 between the ET module 1D and the PA module 2A. The inductor 33A is disposed in series on the first path connecting the external output terminal 101 and the PA module 2A. The inductor 33A is implemented as a chip inductor. However, the inductors 33A is not limited to chip inductors, and may be included in an IPD or may be formed of a planar coil in the motherboard 92.

The external output terminal 101 and the external input terminal 102 are adjacently disposed. This can reduce a total wiring length of a wiring line connecting the external output terminal 101 and the PA module 2A and a wiring line connecting the external input terminal 102 and the PA module 2A. Therefore, the waveform distortion of the power supply voltage V_{ET} output from the ET module 1D can be suppressed, thereby suppressing the efficiency deterioration.

In addition, the external input terminal 102 is connected to the voltage supply circuit 10D. This configuration makes it possible to return the feedback signal of the power supply voltage V_{ET} on the first path to the voltage supply circuit 10D via the external input terminal 102. It is noted that the external input terminal 102 may be connected to the control circuit 70, rather than being connected to the voltage supply circuit 10D.

In addition, the inductor 33A is disposed in series on the first path connecting the external output terminal 101 and the PA module 2A. As a result of this configuration, when the analog ET mode is applied to the ET module 1D, the inductor 33A can be configured to function as the choke coil that blocks a radio frequency signal leaking from the PA module 2A. Therefore, the superimposition of the radio frequency noise on the power supply voltage V_{ET} output from the external output terminal 101 can be suppressed.

It is noted that the inductor 33A may be connected between the external input terminal 102 and a node on the first path. As a result of this configuration, when the analog ET mode is applied to the ET module 1D, the inductor 33A can be configured to function as the choke coil that blocks a radio frequency signal leaking from the PA module 2A. Therefore, it is possible to return the feedback signal of the power supply voltage V_{ET} on the first path to the ET module 1D with high precision via the external input terminal 102.

In addition, a capacitor may be connected to the external output terminal 101 and the external input terminal 102. As a result of this configuration, when the APT mode is applied to the ET module 1D, the above capacitor can be configured to function as a bypass condenser, and the voltage level of the power supply voltage VET can be stabilized.

The inductor 33B is disposed on the motherboard 92 between the ET module 1D and the PA module 2B. The inductor 33B is disposed on the second path connecting the external output terminal 104 and the PA module 2B. The inductor 33B is implemented as a chip inductor. It is noted that the inductor 33B is not limited to a chip inductor and may be included in an IPD or may be formed of the planar coil in the motherboard 92 in various exemplary aspects.

The external output terminal 104 and the external input terminal 105 are adjacently disposed. This can reduce a total wiring length of a wiring line connecting the external output terminal 104 and the PA module 2B and a wiring line connecting the external input terminal 105 and the PA module 2B. Therefore, the waveform distortion of the power supply voltage VET output from the ET module 1D can be suppressed, thereby suppressing the efficiency deterioration.

In addition, the external input terminal 105 is connected to the voltage supply circuit 10D. This configuration makes it possible to return the feedback signal of the power supply voltage V_{ET} on the second path to the voltage supply circuit 10D via the external input terminal 105. It is noted that the external input terminal 105 may be connected to the control circuit 70, rather than being connected to the voltage supply circuit 10D.

In addition, the inductor 33B is disposed in series on the second path connecting the external output terminal 104 and the PA module 2B. As a result of this configuration, when the analog ET mode is applied to the ET module 1D, the inductor 33B can be configured to function as a choke coil that blocks a radio frequency signal leaking from the PA module 2B. Therefore, the superimposition of the radio frequency noise on the power supply voltage V_{ET} output from the external output terminal 104 can be suppressed.

It is noted that the inductor 33B may be connected between the external input terminal 105 and a node on the second path in an exemplary aspect. As a result of this configuration, when the analog ET mode is applied to the ET module 1D, the inductor 33B can be configured to function as a choke coil that blocks a radio frequency signal leaking from the PA module 2B. Therefore, it is possible to return the feedback signal of the power supply voltage VET on the second path to the ET module 1D with high precision via the external input terminal 105.

In addition, a capacitor may be connected to the external output terminal 104 and the external input terminal 105. As a result of this configuration, when the APT mode is applied to the ET module 1D, the above capacitor can be configured to function as the bypass condenser, and the voltage level of the power supply voltage V_{ET} can be stabilized.

In addition, as illustrated in FIG. 10, the module laminate 90 of the ET module 1D has a first side and a second side adjacent to the first side. Moreover, the first side and the second side form at least a part of an outer shape of the module laminate 90 in plan view of the module laminate 90. The external output terminal 101 and the external input terminal 102 are disposed adjacent to the first side. The external output terminal 104 and the external input terminal 105 are not disposed adjacent to the first side and may be disposed adjacent to the second side.

As a result of this, as compared to a configuration in which the external output terminals 101 and 104 as well as the external input terminals 102 and 105 are disposed on a same side, wiring lines supplying the power supply voltage V_{ET} can be disposed at a distance from each other. Therefore, heat dissipation of the ET module 1D can be improved.

### 10. Arrangement of ET Module 1E and Communication Device 5E According to Modification Example 2

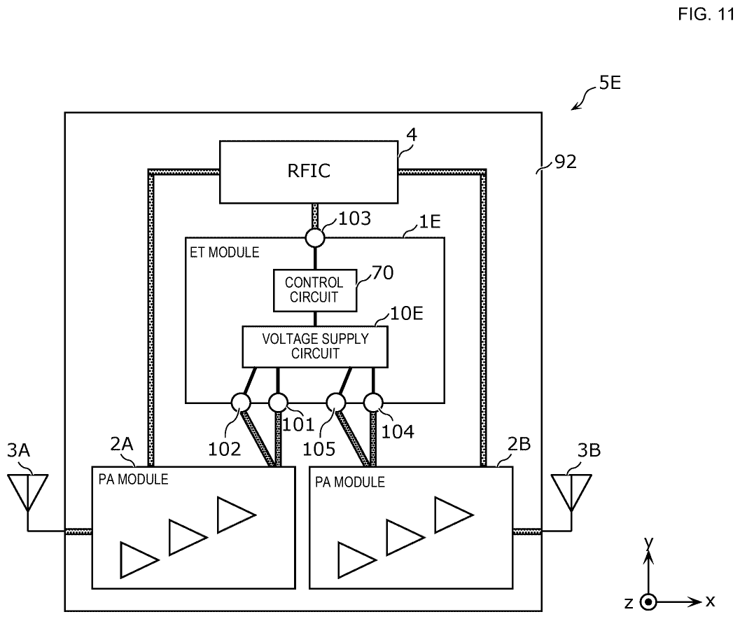

Next, a description is given of the arrangement on the motherboard 92 of the communication device 5E according to Modification Example 2 with reference to FIG. 11. FIG. 11 is a plan view of the communication device 5E according to Modification Example 2. As illustrated in FIG. 11, the communication device 5E includes the motherboard 92, the RFIC 4, the ET module 1E, and the PA modules 2A and 2B. The PA module 2A includes the power amplifiers 41 to 43, and the PA module 2B includes the power amplifiers 44 to 46. As compared to the communication device 5D according to Example 3, the communication device 5E according to this modification example has a different arrangement configuration of the PA modules, the external output terminals, and the external input terminals. In the following, an implementation configuration of the communication device 5E according to this modification example is described with a focus on different points from the implementation configuration of the communication device 5D according to Example 3, and a description of the same points is omitted.

The RFIC 4, the ET module 1E, and the PA modules 2A and 2B are disposed on the main surface of the motherboard 92.

The external output terminal 101 and the external input terminal 102 are adjacently disposed. This can reduce the total wiring length of the wiring line connecting the external output terminal 101 and the PA module 2A and the wiring line connecting the external input terminal 102 and the PA module 2A. Therefore, the waveform distortion of the power supply voltage V_{ET} output from the ET module 1E can be suppressed, thereby suppressing the efficiency deterioration.

The external output terminal 104 and the external input terminal 105 are adjacently disposed. This can reduce the total wiring length of the wiring line connecting the external output terminal 104 and the PA module 2B and the wiring line connecting the external input terminal 105 and the PA module 2B. Therefore, the waveform distortion of the power supply voltage V_{ET} output from the ET module 1E can be suppressed, thereby suppressing the efficiency deterioration.

As illustrated in FIG. 11, the module laminate 90 of the ET module 1E has a first side and a second side adjacent to the first side. Moreover, the first side and the second side form at least a part of the outer shape of the module laminate 90 in plan view of the module laminate 90. The external output terminals 101 and 104 as well as the external input terminals 102 and 105 are disposed on the first side forming at least the part of the outer shape of the ET module 1E.

As a result of this, the PA modules 2A and 2B can be disposed at positions facing the first side of the ET module 1E, so that a size of the communication device 5E can be reduced.

It is noted that in the communication device 5E according to this modification example, a capacitor or an inductor may be disposed between the ET module 1E and the PA modules 2A and 2B, similarly to the communication device 5D according to Example 3.

### 11. Technical Effects

As described above, the ET module 1 according to the embodiment includes the module laminate 90; the external output terminal 101 and the external input terminal 102 disposed on the module laminate 90; and the voltage supply circuit 10 disposed on the module laminate 90 and configured to supply the voltage based on an envelope signal to the PA module 2 through the external output terminal 101. The external input terminal 102 is connected to the first path connecting the external output terminal 101 and the PA module 2, and the external input terminal 102 and the external output terminal 101 are adjacently disposed

This can reduce the total wiring length of the wiring line connecting the external output terminal 101 and the PA module 2 and the wiring line connecting the external input terminal 102 and the PA module 2. Therefore, the waveform distortion of the power supply voltage V_{ET} output from the ET module 1 can be suppressed, thereby suppressing the efficiency deterioration.

In addition, the ET module 1A according to Example 1 includes the module laminate 90; the external output terminal 101 and the external input terminal 102 disposed on the module laminate 90; and the voltage supply circuit 10A including at least one integrated circuit 80 disposed on the module laminate 90. The voltage supply circuit 10A includes at least one switch included in the switched-capacitor circuit 12 and at least one switch included in the output switching circuit 13. The switched-capacitor circuit 12 is configured to generate a plurality of discrete voltages based on the input voltage and output the plurality of discrete voltages generated to the output switching circuit 13. The output switching circuit 13 is configured to selectively output at least one of the plurality of discrete voltages generated to the PA module 2 via the external output terminal 101. The external input terminal 102 is connected to the first path connecting the external output terminal 101 and the PA module 2, and the external input terminal 102 and the external output terminal 101 are adjacently disposed.

This can reduce the total wiring length of the wiring line connecting the external output terminal 101 and the PA module 2 and the wiring line connecting the external input terminal 102 and the PA module 2. Therefore, the waveform distortion of the power supply voltage VET output from the ET module 1A can be suppressed, thereby suppressing the efficiency deterioration.

In addition, for example, in the ET module 1A, the external input terminal 102 and the external output terminal 101 are connected to the capacitor.

As a result of this configuration, when the APT mode is applied to the ET module 1A, the capacitor can be configured to function as the bypass condenser, and the voltage level of the power supply voltage V_{ET} can be stabilized.

In addition, for example, the ET Module 1A further includes the switch 21 that switches between connection and disconnection between the external input terminal 102 and the ground.

As a result of this configuration, when the digital ET mode is applied to the ET module 1A, the switch 21 is in a non-conductive state, so that a radio frequency signal of the wide channel band width (wide modulation band width) can be amplified highly efficiently in the PA module 2. In addition, when the APT mode is applied to the ET module 1A, the switch 21 is in a conductive state, so that the capacitor can be configured to function as the bypass condenser, and the voltage level of the power supply voltage VET can be stabilized.

In addition, for example, in the ET module 1B according to Example 2 and Modification Example 1, at least one of the external input terminal 102 and the external output terminal 101 is connected to the inductor.

As a result of this configuration, when the analog ET mode is applied to the ET module 1B, the inductor can be configured to function as the choke coil that blocks a radio frequency signal leaking from the PA module 2. Therefore, it is possible to return the feedback signal of the power supply voltage V_{ET} on the first path to the ET module 1B with high precision via the external input terminal 102. In addition, the superimposition of the radio frequency noise on the power supply voltage V_{ET} output from the external output terminal 101 can be suppressed.

In addition, for example, in the ET module 1B according to Example 2, the external input terminal 102 is connected to the voltage supply circuit 10B.

This configuration makes it possible to return the feedback signal of the power supply voltage V_{ET} on the first path to the voltage supply circuit 10B via the external input terminal 102.

In addition, for example, the ET module 1D according to Example 3 (the ET module 1E according to Modification Example 2) further includes the external output terminal 104 and the external input terminal 105 disposed on the module laminate 90. The voltage supply circuit 10D (10E) is configured to simultaneously perform supply of the first voltage based on an envelope signal to the PA module 2A via the external output terminal 101 and to supply of the second voltage based on an envelope signal to the PA module 2B via the external output terminal 104. The external input terminal 102 is connected to the first path connecting the external output terminal 101 and the PA module 2A, and the external input terminal 105 is connected to the second path connecting the external output terminal 104 and the PA module 2B. The external input terminal 102 and the external output terminal 101 are adjacently disposed, and the external input terminal 105 and the external output terminal 104 are adjacently disposed.

This can reduce the total wiring length of the wiring line connecting the external output terminal 101 and the PA module 2A and the wiring line connecting the external input terminal 102 and the PA module 2A. This can also reduce the total wiring length of the wiring line connecting the external output terminal 104 and the PA module 2B and the wiring line connecting the external input terminal 105 and the PA module 2B. Therefore, the waveform distortion of the power supply voltage V_{ET} output from the ET module 1D (1E) can be suppressed, thereby suppressing the efficiency deterioration.

In addition, the communication device 5 according to the embodiment includes the RFIC 4 that processes radio frequency signals, the ET module 1 connected to the RFIC 4, the PA module 2, and the motherboard 92 ono which the RFIC 4, the ET module 1, and the PA module 2 are disposed.

This configuration makes it possible to realize the effects of the ET module 1 in the communication device 5.

In addition, for example, the communication device 5A according to Example 1 further includes the capacitor 31 that is disposed on the motherboard 92 and connected to the external input terminal 102 and the external output terminal 101.

As a result of this configuration, when the APT mode is applied to the ET module 1A, the capacitor 31 can be configured to function as the bypass condenser, and the voltage level of the power supply voltage V_{ET} can be stabilized.

In addition, for example, the communication device 5B according to Example 2 (the communication device 5C according to Modification Example 1) further includes the inductor 32 (33) disposed on the motherboard 92 and connected to at least one of the external input terminal 102 and the external output terminal 101.

As a result of this configuration, when the analog ET mode is applied to the ET module 1B, the inductor 32 (33) can be configured to function as the choke coil that blocks a radio frequency signal leaking from the PA module 2. Therefore, it is possible to return the feedback signal of the power supply voltage VET on the first path to the ET module 1B with high precision via the external input terminal 102. Alternatively, it is possible to suppress the superimposition of the radio frequency noise on the power supply voltage VET output from the external output terminal 101.

### Additional Exemplary Embodiment

As described above, the tracker modules and the communication devices according to the exemplary aspects of the present disclosure have been described based on the embodiments, examples, and modification examples. However, the tracker modules and the communication devices according to the present disclosure are not limited to the above-described embodiments, examples, and modification examples. The exemplary aspects of the present disclosure also includes other embodiments realized by combining any of the components in the above-described embodiments, examples, and modification examples, modification examples obtained by applying various modifications to the above-described embodiments, examples, and modification examples without departing from the spirit of the present disclosure, or various types of devices that incorporate the tracker modules or the communication devices described above.

For example, in the circuit configurations of the various circuits according to the above-described embodiment, examples, and modification examples, another circuit element and wiring line, or the like may be inserted between the paths connecting the circuit elements and the signal paths disclosed in the drawings.

In the following, a description is given of the characteristics of the tracker modules and the communication devices described based on the embodiment described above.
<1> A tracker module is provided that includes a module laminate; a first external output terminal and a first external input terminal on the module laminate; and a voltage supply circuit on the module laminate and configured to supply a voltage based on an envelope signal to a power amplifier through the first external output terminal. Moreover, the first external input terminal is connected to a first path that connects the first external output terminal to the power amplifier. The first external input terminal is disposed adjacent to the first external output terminal.
<2> A tracker module is provided that includes a module laminate; a first external output terminal and a first external input terminal on the module laminate; and a voltage supply circuit including at least one integrated circuit on the module laminate. The voltage supply circuit includes at least one switch included in a switched-capacitor circuit and at least one switch included in a first output switching circuit. The switched-capacitor circuit is configured to generate a plurality of discrete voltages based on an input voltage and to output the generated plurality of discrete voltages to the first output switching circuit. The first output switching circuit is configured to selectively output at least one of the generated plurality of discrete voltages to a power amplifier via the first external output terminal, the first external input terminal is connected to a first path connecting the first external output terminal and the power amplifier, and the first external input terminal is disposed adjacent to the first external output terminal.
<3> The tracker module according to <1> or <2>, in which the first external input terminal and the first external output terminal are connected to a capacitor.
<4> The tracker module according to <3>, further including a first switch circuit that switches between connection and disconnection between the first external input terminal and a ground.
<5> The tracker module according to <1> or <2>, in which at least one of the first external input terminal and the first external output terminal is connected to an inductor.
<6> The tracker module according to any one of <1>, <2>, and <5>, in which the first external input terminal is connected to the voltage supply circuit.
<7> The tracker module according to any one of <1> to <6>, further including a second external output terminal and a second external input terminal disposed on the module laminate, in which the voltage supply circuit is configured to simultaneously perform supply of a first voltage based on an envelope signal to a first power amplifier via the first external output terminal and to supply of a second voltage based on an envelope signal to a second power amplifier via the second external output terminal, the second external input terminal is connected to a second path connecting the second external output terminal and the second power amplifier, and the second external input terminal and the second external output terminal are disposed adjacent to each other.
<8> A communication device is provided that includes a signal processing circuit that is configured to process radio frequency signals; the tracker module according to any one of <1> to <7>, and that is connected to the signal processing circuit; the power amplifier; and a motherboard on which the signal processing circuit, the tracker module, and the power amplifier are disposed.
<9> The communication device according to <8>, further including a capacitor disposed on the motherboard and connected to the first external input terminal and the first external output terminal.
<10> The communication device according to <8>, further including an inductor disposed on the motherboard and connected to at least one of the first external input terminal and the first external output terminal.

The exemplary aspects of the present disclosure can be widely used in communication devices, such as mobile phones, as a tracker module that supplies voltages to a power amplifier.

### REFERENCE SIGNS LIST

1, 1A, 1B, 1D, 1E ET MODULE
2, 2A, 2B PA MODULE
3, 3A, 3B ANTENNA
4 RFIC
5, 5A, 5B, 5C, 5D, 5E COMMUNICATION DEVICE
10, 10A, 10B, 10D, 10E VOLTAGE SUPPLY CIRCUIT
11 PRE-REGULATOR CIRCUIT
11A PR SWITCH PORTION
12 SWITCHED-CAPACITOR CIRCUIT
12A SC SWITCH PORTION
13 OUTPUT SWITCHING CIRCUIT
13A OS SWITCH PORTION
14 FILTER CIRCUIT
14A FL SWITCH PORTION
15 DC-DC CONVERTER
16 LINEAR AMPLIFIER CIRCUIT
21 SWITCH
31 CAPACITOR
32, 33, 33A, 33B INDUCTOR
41, 42, 43, 44, 45, 46 POWER AMPLIFIER
51, 52, 53, 54, 55, 56 FILTER
61, 62 SWITCH
70 CONTROL CIRCUIT
70A DIGITAL CONTROL SECTION
80 INTEGRATED CIRCUITS
90 MODULE LAMINATE
90A, 90B MAIN SURFACE
91 RESIN MEMBER
92 MOTHERBOARD
101, 104 EXTERNAL OUTPUT TERMINAL
102, 105 EXTERNAL INPUT TERMINALS
103 CONTROL SIGNAL TERMINAL
110, 131, 132, 133, 134, 140 INPUT TERMINAL
111, 112, 113, 114, 130 OUTPUT TERMINAL
150 EXTERNAL CONNECTION TERMINAL

1. A tracker module comprising:
a module laminate;
a first external output terminal and a first external input terminal on the module laminate; and
a voltage supply circuit on the module laminate and configured to supply a voltage based on an envelope signal to a power amplifier through the first external output terminal,
wherein the first external input terminal is connected to a first path that connects the first external output terminal to the power amplifier, and
wherein the first external input terminal is disposed adjacent to the first external output terminal.

2. The tracker module according to claim 1, wherein the first external input terminal and the first external output terminal are connected to a capacitor.

3. The tracker module according to claim 2, further comprising a first switch circuit configured to switch between a connection and a disconnection between the first external input terminal and a ground.

4. The tracker module according to claim 1, wherein at least one of the first external input terminal and the first external output terminal is connected to an inductor.

5. The tracker module according to claim 1, wherein the first external input terminal is connected to the voltage supply circuit.

6. The tracker module according to claim 1, further comprising:
a second external output terminal and a second external input terminal on the module laminate,
wherein the voltage supply circuit is configured to simultaneously supply a first voltage based on an envelope signal to a first power amplifier via the first external output terminal and to supply a second voltage based on an envelope signal to a second power amplifier via the second external output terminal.

7. The tracker module according to claim 6, wherein:
the second external input terminal is connected to a second path that connects the second external output terminal to the second power amplifier, and
the second external input terminal is disposed adjacent to the second external output terminal.

8. A communication device comprising:
a signal processing circuit configured to process radio frequency signals;
the tracker module according to claim 1 and that is connected to the signal processing circuit;
the power amplifier; and
a motherboard on which the signal processing circuit, the tracker module, and the power amplifier are disposed.

9. The communication device according to claim 8, further comprising a capacitor disposed on the motherboard and connected to the first external input terminal and the first external output terminal.

10. The communication device according to claim 8, further comprising an inductor disposed on the motherboard and connected to at least one of the first external input terminal and the first external output terminal.

11. A tracker module comprising:
a module laminate;
a first external output terminal and a first external input terminal on the module laminate; and
a voltage supply circuit including at least one integrated circuit on the module laminate,
wherein the voltage supply circuit includes at least one switch included in a switched-capacitor circuit and at least one switch included in a first output switching circuit,
wherein the switched-capacitor circuit is configured to generate a plurality of discrete voltages based on an input voltage and to output the generated plurality of discrete voltages to the first output switching circuit,
wherein the first output switching circuit is configured to selectively output at least one of the generated plurality of discrete voltages to a power amplifier via the first external output terminal,
wherein the first external input terminal is connected to a first path that connects the first external output terminal to the power amplifier, and
wherein the first external input terminal is disposed adjacent to the first external output terminal.

12. The tracker module according to claim 11, wherein the first external input terminal and the first external output terminal are connected to a capacitor.

13. The tracker module according to claim 12, further comprising a first switch circuit configured to switch between a connection and a disconnection between the first external input terminal and a ground.

14. The tracker module according to claim 11, wherein at least one of the first external input terminal and the first external output terminal is connected to an inductor.

15. The tracker module according to claim 11, wherein the first external input terminal is connected to the voltage supply circuit.

16. The tracker module according to claim 11, further comprising:
a second external output terminal and a second external input terminal on the module laminate,
wherein the voltage supply circuit is configured to simultaneously supply a first voltage based on an envelope signal to a first power amplifier via the first external output terminal and to supply a second voltage based on an envelope signal to a second power amplifier via the second external output terminal.

17. The tracker module according to claim 16, wherein:
the second external input terminal is connected to a second path that connects the second external output terminal to the second power amplifier, and
the second external input terminal is disposed adjacent to the second external output terminal.

18. A communication device comprising:
a signal processing circuit configured to process radio frequency signals;
the tracker module according to claim 11 and that is connected to the signal processing circuit;
the power amplifier; and
a motherboard on which the signal processing circuit, the tracker module, and the power amplifier are disposed.

19. The communication device according to claim 18, further comprising a capacitor disposed on the motherboard and connected to the first external input terminal and the first external output terminal.

20. The communication device according to claim 18, further comprising an inductor disposed on the motherboard and connected to at least one of the first external input terminal and the first external output terminal.
